(19) United States
(12) Patent Application Publication
(10) Pub. No.: US 2025/0056902 A1
(43) Pub. Date: Feb. 13, 2025

(54) SOLAR CELL MODULE AND METHOD FOR MANUFACTURING THE SAME

(71) Applicant: PANJIT INTERNATIONAL INC., Kaohsiung City (TW)

(72) Inventors: CHUNG-HSIUNG HO, Kaohsiung City (TW); CHIA-WEI CHEN, Kaohsiung City (TW); PING-JUI HSIEH, Kaohsiung City (TW)

(21) Appl. No.: 18/402,776

(22) Filed: Jan. 3, 2024

(30) Foreign Application Priority Data
Aug. 7, 2023 (TW) 112129493

(51) Int. Cl. H01L 31/05; H01L 31/0443; H01L 31/048; H01L 31/18

(52) U.S. Cl. CPC H01L 31/0504; H01L 31/0443; H01L 31/0488; H01L 31/1876

(57) ABSTRACT

A solar cell module and method for manufacturing the same are disclosed. The solar cell module includes a first unit and a second unit. The first unit includes a first solar cell and a first protection element. The first solar cell and the first protection element are electrically coupled in parallel with each other. The second unit includes a second solar cell and a second protection element. The second solar cell and the second protection element are electrically coupled in parallel. The first unit is electrically connected to the second unit.

### BACKGROUND

### 1. Field of the Disclosure

The disclosure relates to a solar cell module and a method for manufacturing the same, in particular to a solar cell module including a protection element, and a method for manufacturing the same.

### 2. Description of the Related Art

The current solar cell module usually includes a plurality of solar cells connected in series. When one or more solar cells of the solar cell module are blocked by foreign objects or blocked by shadows, or are damaged and cannot operate normally, the entire solar cell module will not operate normally. Since most of the solar cell modules are installed outdoors, it is unavoidable that one or more solar cells are blocked by foreign objects or blocked by shadows, or even damaged. Therefore, how to make the solar cell module still generate electricity normally when one or more solar cells cannot operate normally is a critical issue.

### SUMMARY

According to one embodiment of the disclosure, a solar cell module includes a first unit and a second unit. The first unit includes a first solar cell and a first protection element. The first solar cell and the first protection element are electrically coupled in parallel. The second unit includes a second solar cell and a second protection element. The second solar cell and the second protection element are electrically coupled in parallel. The first unit is electrically connected to the second unit.

According to one embodiment of the disclosure, a solar cell module includes a plurality of solar cells and a plurality of protection elements. The protection elements are disposed adjacent to the solar cells. At least one of the protection elements and at least one of the solar cells are electrically coupled in parallel.

According to one embodiment of the disclosure, a method for manufacturing a solar cell module include: (a) disposing a plurality of solar cells and a plurality of protection elements on a carrier; and (b) electrically coupling the plurality of protection elements and the plurality of solar cells in parallel and in one-to-one relationships, and electrically connecting the plurality of solar cells with one another.

### BRIEF DESCRIPTION OF THE DRAWINGS

Various aspects of the disclosure are best understood from the following description when read with the accompanying drawings. It should be noted that, the various features are not drawn to scale in accordance with standard practice in the industry.

FIG. 1 is a perspective top view of a solar cell module according to one embodiment of the disclosure.

FIG. 2 is a partially enlarged view of a first row of the solar cell module of FIG. 1.

FIG. 3 is a partially enlarged view of a fourth row of the solar cell module of FIG. 1.

FIG. 4 is a perspective bottom view of the solar cell module of FIG. 1.

FIG. 5 is a partially enlarged view of the first row of the solar cell module of FIG. 4.

FIG. 6 is a partially enlarged view of the fourth row of the solar cell module of FIG. 4.

FIG. 7 is a cross-sectional view taken along a line I-I on the solar cell module of FIG. 1.

FIG. 8 is a partially enlarged view of the solar cell module of FIG. 7.

FIG. 9 is a schematic electrical circuit diagram of the solar cell module of FIG. 1.

FIG. 10 is a perspective top view of a solar cell module according to one embodiment of the disclosure.

FIG. 11 is a cross-sectional view taken along a line II-II on the solar cell module of FIG. 10.

FIG. 12 is a perspective top view of a solar cell module according to one embodiment of the disclosure.

FIG. 13 is a schematic electrical circuit diagram of the solar cell module of FIG. 12.

FIG. 14 is a cross-sectional view of a solar cell module according to one embodiment of the disclosure.

FIG. 15 is a partially enlarged view of the solar cell module of FIG. 14.

FIG. 16 is a cross-sectional view of a solar cell module according to one embodiment of the disclosure.

FIG. 17 is a partially enlarged view of the solar cell module of FIG. 16.

FIG. 18 is a cross-sectional view of a solar cell module according to one embodiment of the disclosure.

FIG. 19 is a partially enlarged view of the solar cell module of FIG. 18.

FIG. 20 through FIG. 35 illustrate an example of a method for manufacturing a solar cell module according to some embodiments of the present disclosure.

FIG. 36 through FIG. 38 illustrate an example of a method for manufacturing a solar cell module according to some embodiments of the present disclosure.

FIG. 39 through FIG. 44 illustrate an example of a method for manufacturing a solar cell module according to some embodiments of the present disclosure.

### DETAILED DESCRIPTION

The components, values, operations, materials and configurations in the following disclosure are merely embodiments or examples and are not intended to be limiting. For example, a first element being formed over or on a second element may include different implementations. The first element and the second element may be in direct contact. Alternatively, the first element and the second element may not be in direct contact, and an additional element between the first element and the second element may be included.

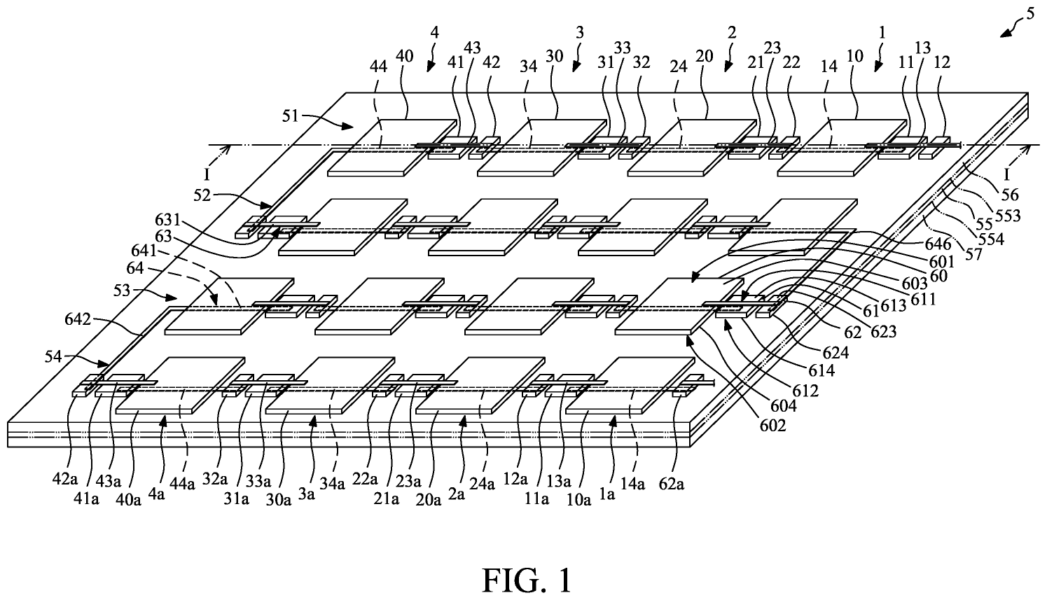

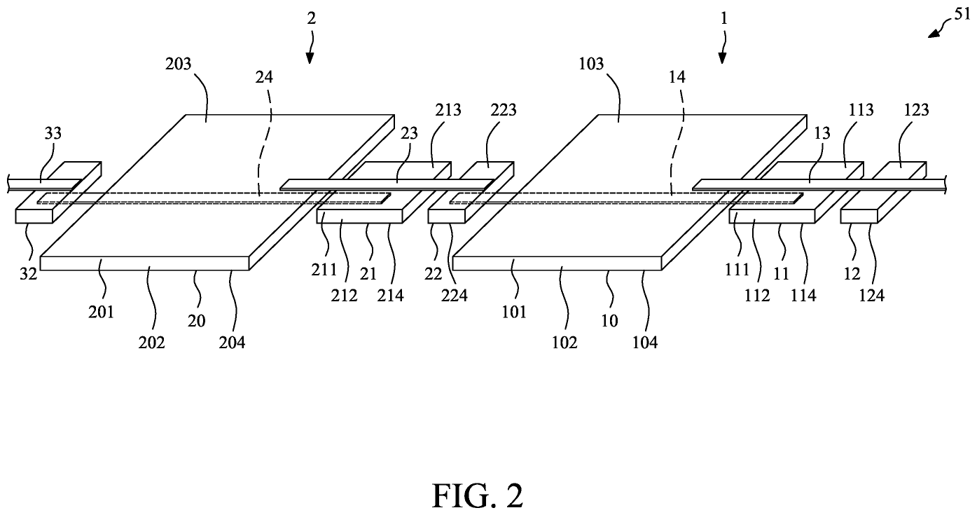

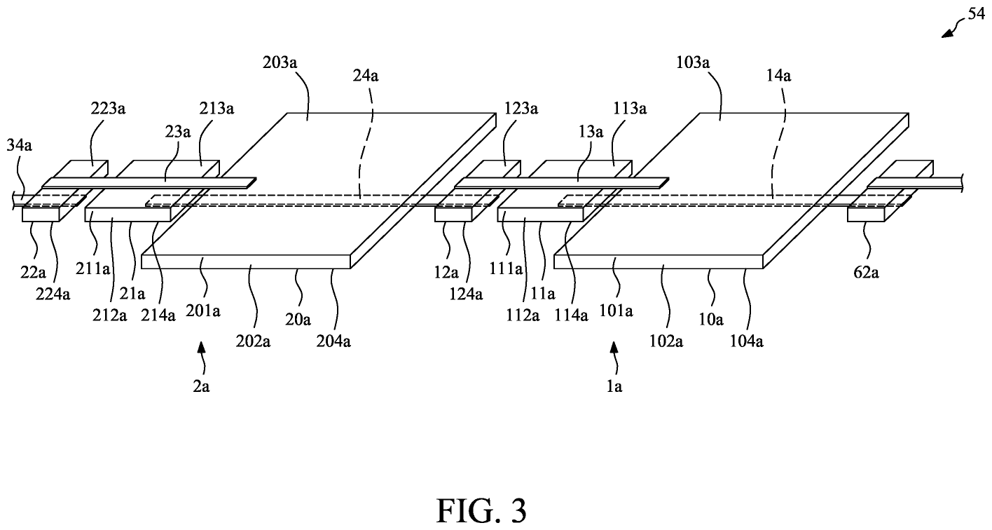

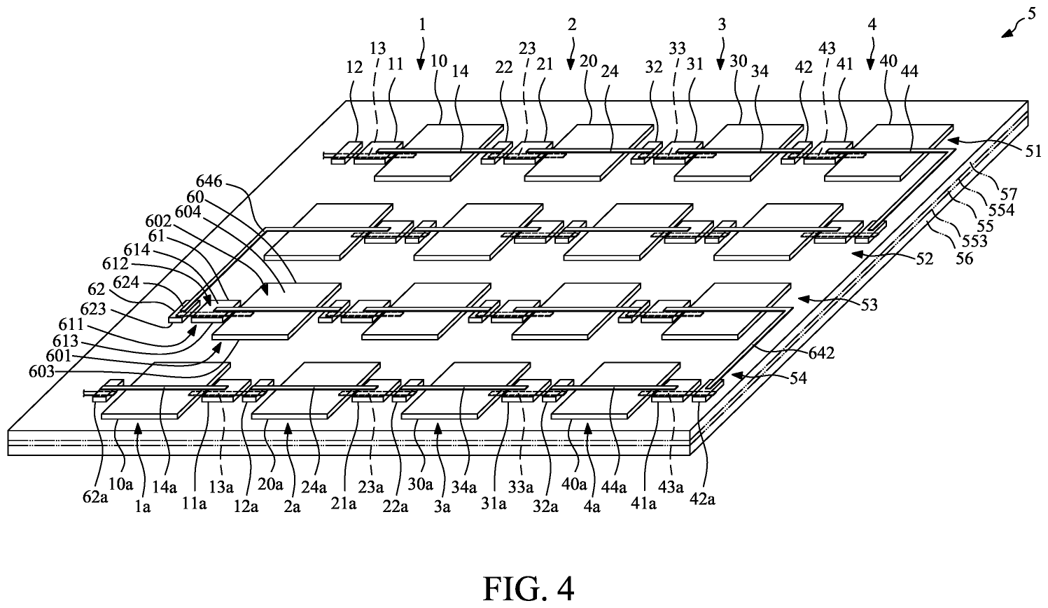

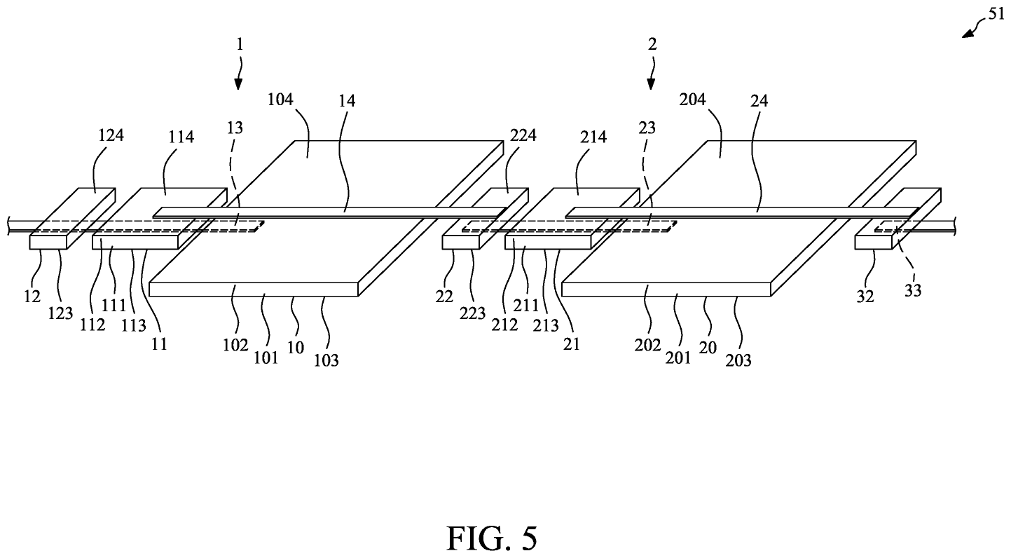

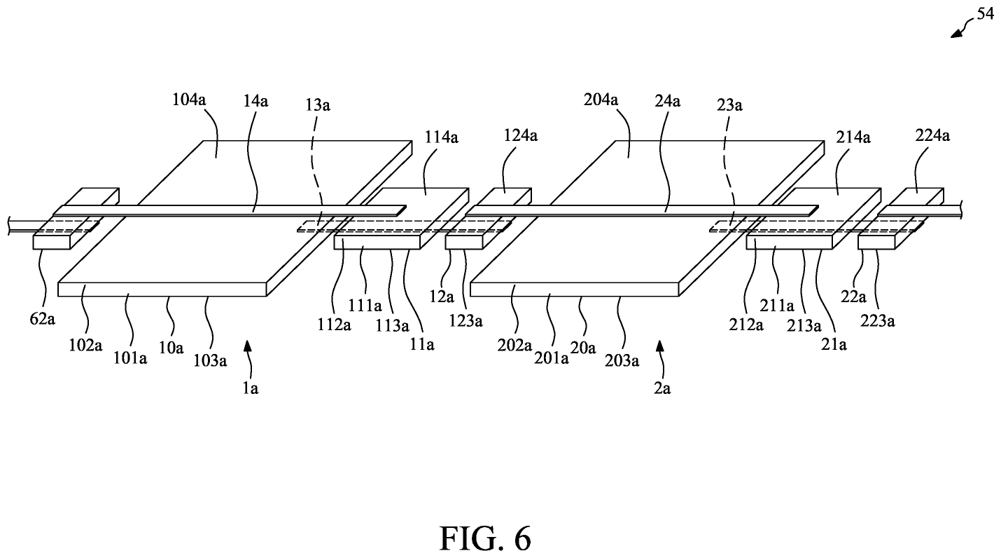

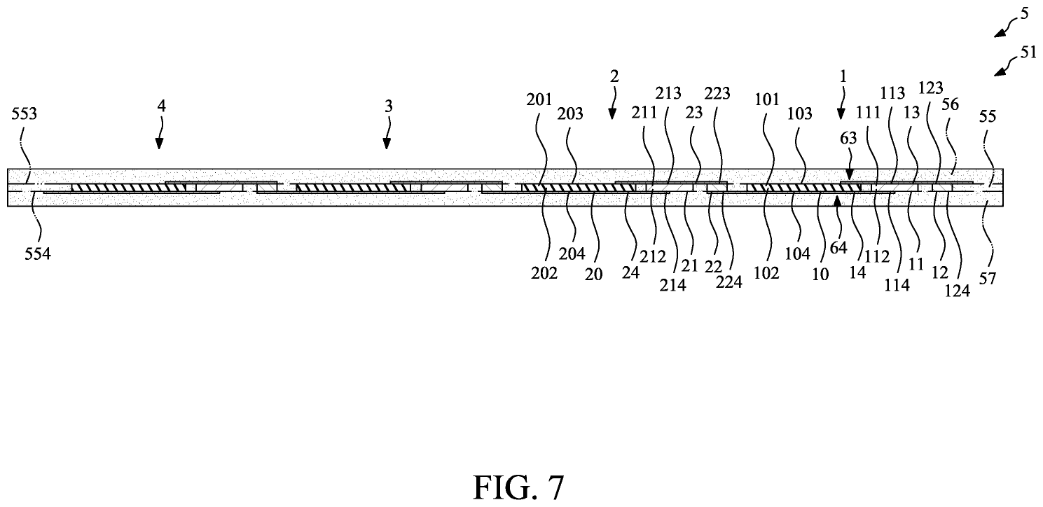

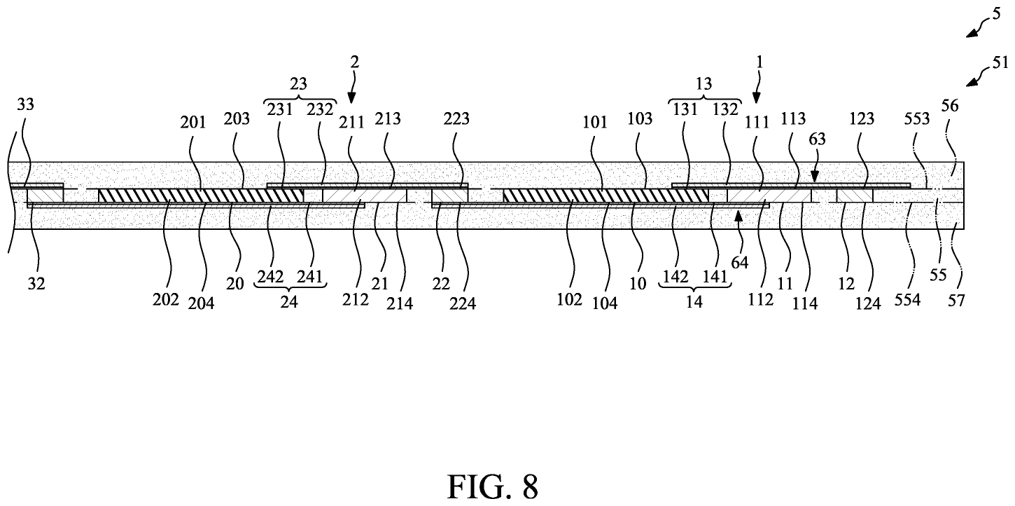

FIG. 1 is a perspective top view of a solar cell module 5 according to one embodiment of the disclosure. FIG. 2 is a partially enlarged view of a first row 51 of the solar cell module 5 of FIG. 1. FIG. 3 is a partially enlarged view of a fourth row 54 of the solar cell module 5 of FIG. 1. FIG. 4 is a perspective bottom view of the solar cell module 5 of FIG. 1. FIG. 5 is a partially enlarged view of the first row 51 of the solar cell module 5 of FIG. 4. FIG. 6 is a partially enlarged view of the fourth row 54 of the solar cell module 5 of FIG. 4. FIG. 7 is a cross-sectional view taken along a line I-I on the solar cell module 5 of FIG. 1. FIG. 8 is a partially enlarged view of the solar cell module 5 of FIG. 7.

The solar cell module 5 may include a plurality of solar cells 60, a plurality of protection elements 61, a plurality of conductive elements 62, an upper conductive structure 63, a lower conductive structure 64, a main protection portion 55, an upper transparent protection portion 56 and a lower transparent protection portion 57. In one embodiment, the solar cells 60, the protection elements 61 and the conductive elements 62 are arranged in an array. Thus, the solar cells 60, the protection elements 61 and the conductive elements 62 may include a first row 51, a second row 52, a third row 53 and a fourth row 54.

The solar cell 60 may be configured to convert or transform light energy into electrical energy, and may include a negative electrode 601 (e.g., an upper portion or a first electrode) and a positive electrode 602 (e.g., a lower portion or a second electrode). The positive electrode 602 (e.g., the lower portion or the second electrode) is opposite to the negative electrode 601 (e.g., the upper portion or the first electrode). For example, the solar cells 60 may include a first solar cell 10, 10a, a second solar cell 20, 20a, a third solar cell 30, 30a and a fourth solar cell 40, 40a. The protection element 61 may be configured to provide a by-pass circuit, so as to protect the solar cell 60. The protection element 61 may be a diode element such as a Schottky diode, and may include a P electrode 611 (e.g., an upper portion or a first electrode) and an N electrode 612 (e.g., a lower portion or a second electrode). The N electrode 612 (e.g., the lower portion or the second electrode) is opposite to the P electrode 611 (e.g., the upper portion or the first electrode). For example, the protection elements 61 may include a first protection element 11, 11a, a second protection element 21, 21a, a third protection element 31, 31a and a fourth protection element 41, 41a. The conductive element 62 may be a metal block structure or an interconnection via, and may be configured to electrically connect or electrically conduct the upper conductive structure 63 and the lower conductive structure 64. For example, the conductive elements 62 may include a first conductive element 12, 12a, a second conductive element 22, 22a, a third conductive element 32, 32a and a fourth conductive element 42, 42a.

In one embodiment, the upper conductive structure 63 may include a plurality of upper conductive circuits 631 spaced apart from each other. The upper conductive circuit 631 may be a redistribution layer (RDL) or a conductive segment, and may be formed by an electroplating process. The upper conductive circuit 631 may include a seed layer (e.g., titanium-copper-alloy seed layer) and a conductive material (e.g., copper or copper alloy) disposed on the seed layer. In one embodiment, the lower conductive structure 64 may include a plurality of lower conductive circuits 641 and at least one lower connecting segment 642, 646. The lower conductive circuits 641 are spaced apart from each other. The lower connecting segment 642, 646 electrically connects different rows (e.g., the first row 51, the second row 52, the third row 53 and the fourth row 54) of the solar cells 60, the protection elements 61 and the conductive elements 62, so that the different rows (e.g., the first row 51, the second row 52, the third row 53 and the fourth row 54) of the solar cells 60, the protection elements 61 and the conductive elements 62 are electrically coupled (e.g., electrically connected) in parallel or in series.

The lower conductive circuit 641 and the lower connecting segment 642, 646 may be a redistribution layer (RDL) or a conductive segment, and may be formed by an electroplating process. The lower conductive circuit 641 and the lower connecting segment 642, 646 may include a seed layer (e.g., titanium-copper-alloy seed layer) and a conductive material (e.g., copper or copper alloy) disposed on the seed layer. The upper conductive structure 63 (e.g., the upper conductive circuits 631) is opposite to the lower conductive structure 64 (e.g., the lower conductive circuits 641 and the lower connecting segment 642, 646). The upper conductive structure 63 may be disposed over the solar cells 60, the protection elements 61 and the conductive elements 62. The lower conductive structure 64 may be disposed under the solar cells 60, the protection elements 61 and the conductive elements 62.

The upper conductive circuit 631 is electrically connected to the negative electrode 601 of the solar cell 60 and the P electrode 611 of the protection element 61 simultaneously or at the same time. The lower conductive circuit 641 is electrically connected to the positive electrode 602 of the solar cell 60 and the N electrode 612 of the protection element 61 simultaneously or at the same time. Therefore, the protection elements 61 and the solar cells 60 are coupled in parallel (e.g., “electrically coupled in parallel”, “electrically connected in parallel”, “in-parallel electrical connection”, or “electrically conducted in parallel”) and in one-to-one relationships. That is, a solar cell 60 will be coupled in parallel with a corresponding protection element 61. At least one of the protection elements 61 and at least one of the solar cells 60 are electrically coupled in parallel. In one embodiment, the number of the protection elements 61 may be equal to, less than, or greater than the number of the solar cells 60. That is, more than two solar cells 60 may be coupled in parallel with one protection element 61. In addition, the protection elements 61 are respectively disposed between the solar cells 60. That is, a protection element 61 may be disposed between adjacent two solar cells 60.

The upper conductive circuit 631 extends to a position over the conductive element 62 and is electrically connected to the conductive element 62. The lower conductive circuit 641 extends to a position under the conductive element 62 and is electrically connected to the conductive element 62. Thus, one conductive element 62 is electrically connected (or electrically conducted) to different electrodes of adjacent solar cells 60 respectively. For example, the conductive element 62 is electrically connected to a negative electrode 601 of a solar cell 60 and a positive electrode 602 of an adjacent solar cell 60. In addition, the conductive element 62 is electrically connected (or electrically conducted) to different electrodes of adjacent protection elements 61 respectively. For example, the conductive element 62 is electrically connected to a P electrode 611 of a protection element 61 and an N electrode 612 of an adjacent protection element 61. Thus, the solar cells 60 disposed at a same row are electrically coupled in series, and the protection elements 61 disposed at a same row are electrically coupled in series. The conductive elements 62 may be disposed between the solar cells 60 respectively. That is, there may be one conductive element 62 disposed between adjacent two solar cells 60. In addition, the protection element 61 may be disposed between the conductive element 62 and the solar cell 60.

The main protection portion 55 (e.g., a main protection layer) is configured to encapsulate the solar cells 60, the protection elements 61 and the conductive element 62. In one embodiment, the main protection portion 55 may include a dielectric material or an insulation material. In one embodiment, the main protection portion 55 may include a transparent material, such as ethylene-vinyl acetate copolymer (EVA). In one embodiment, the solar cell 60 may have a first surface 603 (e.g., a top surface) and a second surface 604 (e.g., a bottom surface) opposite to the first surface 603. The negative electrode 601 is adjacent to the first surface 603. The positive electrode 602 is adjacent to the second surface 604. The protection element 61 may have a first surface 613 (e.g., a top surface) and a second surface 614 (e.g., a bottom surface) opposite to the first surface 613. The P electrode 611 is adjacent to the first surface 613. The N electrode 612 is adjacent to the second surface 614.

The conductive element 62 may have a first surface 623 (e.g., a top surface) and a second surface 624 (e.g., a bottom surface) opposite to the first surface 623. In one embodiment, a thickness of the main protection portion 55 may be substantially equal to a thickness of the solar cell 60, a thickness of the protection element 61 and a thickness of the conductive element 62. Thus, a first surface 553 (e.g., a top surface) of the main protection portion 55 is substantially coplanar with or level with the first surface 603 of the solar cell 60, the first surface 613 of the protection element 61 and the first surface 623 of the conductive element 62. In other words, the main protection portion 55 may not cover the first surface 603 of the solar cell 60, the first surface 613 of the protection element 61 and the first surface 623 of the conductive element 62. The first surface 603 of the solar cell 60, the first surface 613 of the protection element 61 and the first surface 623 of the conductive element 62 may be exposed by the main protection portion 55.

A second surface 554 (e.g., a bottom surface) of the main protection portion 55 is substantially coplanar with or level with the second surface 604 of the solar cell 60, the second surface 614 of the protection element 61 and the second surface 624 of the conductive element 62. In other words, the main protection portion 55 may not cover the second surface 604 of the solar cell 60, the second surface 614 of the protection element 61 and the second surface 624 of the conductive element 62. The second surface 604 of the solar cell 60, the second surface 614 of the protection element 61 and the second surface 624 of the conductive element 62 may be exposed by the main protection portion 55.

In another embodiment, the thickness of the main protection portion 55 may be greater than the thickness of the solar cell 60, the thickness of the protection element 61 and the thickness of the conductive element 62. Thus, the first surface 553 of the main protection portion 55 may be higher than the first surface 603 of the solar cell 60, the first surface 613 of the protection element 61 and the first surface 623 of the conductive element 62. In other words, the main protection portion 55 may cover the first surface 603 of the solar cell 60, the first surface 613 of the protection element 61 and the first surface 623 of the conductive element 62.

The upper conductive structure 63 (e.g., the upper conductive circuits 631) may be disposed on the first surface 553 of the main protection portion 55, and may be disposed over the solar cells 60, the protection elements 61 and the conductive elements 62. In one embodiment, the first surface 603 of the solar cell 60, the first surface 613 of the protection element 61 and the first surface 623 of the conductive element 62 may be exposed by the main protection portion 55, thus, the upper conductive structure 63 (e.g., the upper conductive circuits 631) may directly contact and electrically connect the first surface 603 of the solar cell 60, the first surface 613 of the protection element 61 and the first surface 623 of the conductive element 62. In another embodiment, the first surface 603 of the solar cell 60, the first surface 613 of the protection element 61 and the first surface 623 of the conductive element 62 may be covered by the main protection portion 55, thus, the upper conductive structure 63 (e.g., the upper conductive circuits 631) may be electrically connected to the first surface 603 of the solar cell 60, the first surface 613 of the protection element 61 and the first surface 623 of the conductive element 62 through a plurality of conductive vias in the main protection portion 55.

The upper transparent protection portion 56 (e.g., an upper transparent layer) may be configured to cover an upper portion of the main protection portion 55, the upper conductive structure 63 (e.g., the upper conductive circuits 631), a plurality of upper portions of the solar cells 60, a plurality of upper portions of the protection elements 61 and a plurality of upper portions of conductive elements 62. In one embodiment, the upper transparent protection portion 56 may include a dielectric material or an insulation material. In one embodiment, the upper transparent protection portion 56 may include a transparent material, such as ethylene-vinyl acetate copolymer (EVA). In one embodiment, the upper transparent protection portion 56 may cover and contact the first surface 603 of the solar cell 60, the first surface 613 of the protection element 61 and the first surface 623 of the conductive element 62. In another embodiment, the upper transparent protection portion 56 may not contact the first surface 603 of the solar cell 60, the first surface 613 of the protection element 61 and the first surface 623 of the conductive element 62.

In one embodiment, a material of the upper transparent protection portion 56 may be different from a material of the main protection portion 55. Thus, there may be a visible interface or an obvious interface (e.g., the first surface 553 of the main protection portion 55) formed between the upper transparent protection portion 56 and the main protection portion 55. The visible interface herein may be also referred to as “a first visible interface” or “an upper visible interface”. In another embodiment, the material of the upper transparent protection portion 56 may be same as the material of the main protection portion 55. Thus, there may be no obvious interface or visible interface formed between the upper transparent protection portion 56 and the main protection portion 55. That is, the first surface 553 of the main protection portion 55 does not actually exist.

The lower conductive structure 64 (e.g., the lower conductive circuits 641 and the lower connecting segment 642, 646) may be disposed on the second surface 554 of the main protection portion 55, and may be disposed under the solar cells 60, the protection elements 61 and the conductive elements 62. In one embodiment, the second surface 604 of the solar cell 60, the second surface 614 of the protection element 61 and the second surface 624 of the conductive element 62 may be exposed by the main protection portion 55, thus, the lower conductive structure 64 (e.g., the lower conductive circuits 641) may be disposed on the second surface 604 of the solar cell 60, the second surface 614 of the protection element 61 and the second surface 624 of the conductive element 62. The lower conductive structure 64 (e.g., the lower conductive circuits 641) may directly contact and electrically connect the second surface 604 of the solar cell 60, the second surface 614 of the protection element 61 and the second surface 624 of the conductive element 62.

The lower transparent protection portion 57 (e.g., a lower transparent layer) may be configured to cover a lower portion of the main protection portion 55, the lower conductive structure 64 (e.g., the lower conductive circuits 641 and the lower connecting segment 642, 646), a plurality of lower portions of the solar cells 60, a plurality of lower portions of the protection elements 61 and a plurality of lower portions of conductive elements 62. In one embodiment, the lower transparent protection portion 57 may include a dielectric material or an insulation material. In one embodiment, the lower transparent protection portion 57 may include a transparent material, such as ethylene-vinyl acetate copolymer (EVA). In one embodiment, the lower transparent protection portion 57 may cover and contact the second surface 604 of the solar cell 60, the second surface 614 of the protection element 61 and the second surface 624 of the conductive element 62.

In one embodiment, a material of the lower transparent protection portion 57 may be different from the material of the main protection portion 55. Thus, there may be a visible interface or an obvious interface (e.g., the second surface 554 of the main protection portion 55) formed between the lower transparent protection portion 57 and the main protection portion 55. The visible interface herein may be also referred to as “a second visible interface” or “a lower visible interface”. In another embodiment, the material of the lower transparent protection portion 57 may be same as the material of the main protection portion 55. Thus, there may be no obvious interface or visible interface formed between the lower transparent protection portion 57 and the main protection portion 55. That is, the second surface 554 of the main protection portion 55 does not actually exist.

As shown in FIG. 1, FIG. 2, FIG. 4 and FIG. 5, in one embodiment, the first row 51 may include a first solar cell 10, a second solar cell 20, a third solar cell 30, a fourth solar cell 40, a first protection element 11, a second protection element 21, a third protection element 31, a fourth protection element 41, a first conductive element 12, a second conductive element 22, a third conductive element 32 and a fourth conductive element 42. The upper conductive circuits 631 of the upper conductive structure 63 may include a first upper conductive circuit 13, a second upper conductive circuit 23, a third upper conductive circuit 33 and a fourth upper conductive circuit 43. The lower conductive circuits 641 of the lower conductive structure 64 may include a first lower conductive circuit 14, a second lower conductive circuit 24, a third lower conductive circuit 34 and a fourth lower conductive circuit 44.

For example, the first solar cell 10, the first protection element 11 and the first conductive element 12 form a first unit 1. The second solar cell 20, the second protection element 21 and the second conductive element 22 form a second unit 2. The third solar cell 30, the third protection element 31 and the third conductive element 32 form a third unit 3. The fourth solar cell 40, the fourth protection element 41 and the fourth conductive element 42 form a fourth unit 4. Thus, the solar cell module 5 may include a plurality of units (e.g., the first unit 1, the second unit 2, the third unit 3 and the fourth unit 4). The first unit 1 may include the first solar cell 10, the first protection element 11 and the first conductive element 12. The second unit 2 may include the second solar cell 20, the second protection element 21 and the second conductive element 22. The third unit 3 may include the third solar cell 30, the third protection element 31 and the third conductive element 32. The fourth unit 4 may include the fourth solar cell 40, the fourth protection element 41 and the fourth conductive element 42. In one embodiment, the first unit 1, the second unit 2, the third unit 3 and the fourth unit 4 are electrically connected with one another, for example, they may be electrically coupled with one another in series. In one embodiment, the first conductive element 12 may be omitted.

The first solar cell 10 may include a negative electrode 101 (e.g., an upper portion or a first electrode) and a positive electrode 102 (e.g., a lower portion or a second electrode). The positive electrode 102 (e.g., the lower portion or the second electrode) is opposite to the negative electrode 101 (e.g., the upper portion or the first electrode). The first solar cell 10 may have a first surface 103 (e.g., a top surface or an upper surface) and a second surface 104 (e.g., a bottom surface or a lower surface). The second surface 104 is opposite to the first surface 103. The negative electrode 101 is adjacent to the first surface 103. The positive electrode 102 is adjacent to the second surface 104.

The first protection element 11 may be disposed between the first solar cell 10 and the first conductive element 12. The first protection element 11 may be configured to provide a by-pass circuit, so as to protect the first solar cell 10. The first protection element 11 may be a diode element, and may include a P electrode 111 (e.g., an upper portion or a first electrode) and an N electrode 112 (e.g., a lower portion or a second electrode). The N electrode 112 (e.g., the lower portion or the second electrode) is opposite to the P electrode 111 (e.g., the upper portion or the first electrode). The first protection element 11 may have a first surface 113 (e.g., a top surface or an upper surface) and a second surface 114 (e.g., a bottom surface or a lower surface). The second surface 114 is opposite to the first surface 113. The P electrode 111 is adjacent to the first surface 113. The N electrode 112 is adjacent to the second surface 114.

The first conductive element 12 may be a metal block structure or an interconnection via, and may be configured to electrically connect or electrically conduct the first upper conductive circuit 13 of the upper conductive structure 63 and a lower conductive circuit of the lower conductive structure 64. The first conductive element 12 may have a first surface 123 (e.g., a top surface or an upper surface) and a second surface 124 (e.g., a bottom surface or a lower surface) opposite to the first surface 123.

The first upper conductive circuit 13 may include a seed layer 131 and a conductive material 132 (FIG. 8) disposed on the seed layer 131. The first lower conductive circuit 14 may include a seed layer 141 and a conductive material 142 (FIG. 8) disposed on the seed layer 141. The first upper conductive circuit 13 is electrically connected to the negative electrode 101 of the first solar cell 10 and the P electrode 111 of the first protection element 11 simultaneously or at the same time. The first lower conductive circuit 14 is electrically connected to the positive electrode 102 of the first solar cell 10 and the N electrode 112 of the first protection element 11 simultaneously or at the same time. Therefore, the first protection element 11 and the first solar cell 10 are coupled in parallel (e.g., “electrically coupled in parallel”, “electrically connected in parallel”, “in-parallel electrical connection”, or “electrically conducted in parallel”).

The first upper conductive circuit 13 may further extend to a position over the first conductive element 12 and may be electrically connected to the first conductive element 12. Thus, the first upper conductive circuit 13 is electrically connected to the negative electrode 101 of the first solar cell 10, the P electrode 111 of the first protection element 11 and the first conductive element 12 simultaneously or at the same time. In one embodiment, a bottom surface of the first upper conductive circuit 13 may contact the first surface 103 of the first solar cell 10, the first surface 113 of the first protection element 11 and the first surface 123 of the first conductive element 12 simultaneously or at the same time. In addition, the first lower conductive circuit 14 may further extend to a position under the second conductive element 22 and may be electrically connected to the second conductive element 22. Thus, the first lower conductive circuit 14 is electrically connected to the positive electrode 102 of the first solar cell 10, the N electrode 112 of the first protection element 11 and the second conductive element 22 simultaneously or at the same time. In one embodiment, a top surface of the first lower conductive circuit 14 may contact the second surface 104 of the first solar cell 10, the second surface 114 of the first protection element 11 and the second surface 224 of the second conductive element 22 simultaneously or at the same time. Thus, the first conductive element 12 may be electrically connected to the first electrode (e.g., the negative electrode 101) of the first solar cell 10 and the first electrode (e.g., the P electrode 111) of the first protection element 11 through the first upper conductive circuit 13 directly, and may be not electrically connected to the second electrode (e.g., the positive electrode 102) of the first solar cell 10 and the second electrode (e.g., the N electrode 112) of the first protection element 11 directly.

The second solar cell 20 may include a negative electrode 201 (e.g., an upper portion or a first electrode) and a positive electrode 202 (e.g., a lower portion or a second electrode). The positive electrode 202 (e.g., the lower portion or the second electrode) is opposite to the negative electrode 201 (e.g., the upper portion or the first electrode). The second solar cell 20 may have a first surface 203 (e.g., a top surface or an upper surface) and a second surface 204 (e.g., a bottom surface or a lower surface). The second surface 204 is opposite to the first surface 203. The negative electrode 201 is adjacent to the first surface 203. The positive electrode 202 is adjacent to the second surface 204.

The second protection element 21 may be disposed between the second solar cell 20 and the second conductive element 22. The second protection element 21 may be configured to provide a by-pass circuit, so as to protect the second solar cell 20. The second protection element 21 may be a diode element, and may include a P electrode 211 (e.g., an upper portion or a first electrode) and an N electrode 212 (e.g., a lower portion or a second electrode). The N electrode 212 (e.g., the lower portion or the second electrode) is opposite to the P electrode 211 (e.g., the upper portion or the first electrode). The second protection element 21 may have a first surface 213 (e.g., a top surface or an upper surface) and a second surface 214 (e.g., a bottom surface or a lower surface). The second surface 214 is opposite to the first surface 213. The P electrode 211 is adjacent to the first surface 213. The N electrode 212 is adjacent to the second surface 214.

The second conductive element 22 may be a metal block structure or an interconnection via, and may be configured to electrically connect or electrically conduct the second upper conductive circuit 23 of the upper conductive structure 63 and a first lower conductive circuit 14 of the lower conductive structure 64. Thus, the first unit 1 and the second unit 2 are coupled (e.g., electrically coupled) in series. The second conductive element 22 may have a first surface 223 (e.g., a top surface or an upper surface) and a second surface 224 (e.g., a bottom surface or a lower surface) opposite to the first surface 223.

The second upper conductive circuit 23 and the first upper conductive circuit 13 are spaced apart from each other, and they are the segments that independent from each other. That is, the second upper conductive circuit 23 does not directly connect to the first upper conductive circuit 13. The second upper conductive circuit 23 may include a seed layer 231 and a conductive material 232 (FIG. 8) disposed on the seed layer 231. The second lower conductive circuit 24 and the first lower conductive circuit 14 are spaced apart from each other, and they are the segments that independent from each other. That is, the second lower conductive circuit 24 does not directly connect to the first lower conductive circuit 14. The second lower conductive circuit 24 may include a seed layer 241 and a conductive material 242 (FIG. 8) disposed on the seed layer 241. The second upper conductive circuit 23 is electrically connected to the negative electrode 201 of the second solar cell 20 and the P electrode 211 of the second protection element 21 simultaneously or at the same time. The second lower conductive circuit 24 is electrically connected to the positive electrode 202 of the second solar cell 20 and the N electrode 212 of the second protection element 21 simultaneously or at the same time. Therefore, the second protection element 21 and the second solar cell 20 are coupled in parallel (e.g., “electrically coupled in parallel”, “electrically connected in parallel”, “in-parallel electrical connection”, or “electrically conducted in parallel”).

The second upper conductive circuit 23 may further extend to a position over the second conductive element 22 and may be electrically connected to the second conductive element 22. Thus, the second upper conductive circuit 23 is electrically connected to the negative electrode 201 of the second solar cell 20, the P electrode 211 of the second protection element 21 and the second conductive element 22 simultaneously or at the same time. In addition, the second lower conductive circuit 24 may further extend to a position under the third conductive element 32 and may be electrically connected to the third conductive element 32. Thus, the second lower conductive circuit 24 is electrically connected to the positive electrode 202 of the second solar cell 20, the N electrode 212 of the second protection element 21 and the third conductive element 32 simultaneously or at the same time. Thus, the second conductive element 22 may be electrically connected to the first electrode (e.g., the negative electrode 201) of the second solar cell 20 and the first electrode (e.g., the P electrode 211) of the second protection element 21 through the second upper conductive circuit 23 directly, and may be not electrically connected to the second electrode (e.g., the positive electrode 202) of the second solar cell 20 and the second electrode (e.g., the N electrode 212) of the second protection element 21 directly. Further, the second conductive element 22 may be electrically connected to the second electrode (e.g., the positive electrode 102) of the first solar cell 10 and the second electrode (e.g., the N electrode 112) of the first protection element 11 through the first lower conductive circuit 14 directly.

In addition, a first electrical path is formed between the first solar cell 10 and the first protection element 11. A second electrical path is formed between the second solar cell 20 and the second protection element 21. A length of the first electrical path is substantially equal to a length of the second electrical path.

As shown in FIG. 1 and FIG. 4, the arrangement of components in the first row 51 is the same as the arrangement of components in the third row 53, and the arrangement of components in the second row 52 is the same as the arrangement of components in the fourth row 54. The arrangement of components in the first row 51 is different from the arrangement of components in the second row 52, and the arrangement of components in the first row 51 is different from the arrangement of components in the fourth row 54.

As shown in FIG. 1, FIG. 3, FIG. 4 and FIG. 6, in one embodiment, the fourth row 54 may include a first solar cell 10a, a second solar cell 20a, a third solar cell 30a, a fourth solar cell 40a, a first protection element 11a, a second protection element 21a, a third protection element 31a, a fourth protection element 41a, a first conductive element 12a, a second conductive element 22a, a third conductive element 32a and a fourth conductive element 42a. The upper conductive circuits 631 of the upper conductive structure 63 may include a first upper conductive circuit 13a, a second upper conductive circuit 23a, a third upper conductive circuit 33a and a fourth upper conductive circuit 43a. The lower conductive circuits 641 of the lower conductive structure 64 may include a first lower conductive circuit 14a, a second lower conductive circuit 24a, a third lower conductive circuit 34a and a fourth lower conductive circuit 44a.

For example, the first solar cell 10a, the first protection element 11a and the first conductive element 12a form a first unit 1a. The second solar cell 20a, the second protection element 21a and the second conductive element 22a form a second unit 2a. The third solar cell 30a, the third protection element 31a and the third conductive element 32a form a third unit 3a. The fourth solar cell 40a, the fourth protection element 41a and the fourth conductive element 42a form a fourth unit 4a. In one embodiment, the first unit 1a, the second unit 2a, the third unit 3a and the fourth unit 4a are electrically connected with one another, for example, they may be electrically coupled with one another in series. In one embodiment, the fourth row 54 may include a conductive element 62a.

The first solar cell 10a may include a negative electrode 101a (e.g., an upper portion or a first electrode) and a positive electrode 102a (e.g., a lower portion or a second electrode). The positive electrode 102a (e.g., the lower portion or the second electrode) is opposite to the negative electrode 101a (e.g., the upper portion or the first electrode). The first solar cell 10a may have a first surface 103a (e.g., a top surface or an upper surface) and a second surface 104a (e.g., a bottom surface or a lower surface). The second surface 104a is opposite to the first surface 103a. The negative electrode 101a is adjacent to the first surface 103a. The positive electrode 102a is adjacent to the second surface 104a.

The first protection element 11a may be disposed between the first solar cell 10a and the first conductive element 12a. The first protection element 11a may be configured to provide a by-pass circuit, so as to protect the first solar cell 10a. The first protection element 11a may be a diode element, and may include a P electrode 111a (e.g., an upper portion or a first electrode) and an N electrode 112a (e.g., a lower portion or a second electrode). The N electrode 112a (e.g., the lower portion or the second electrode) is opposite to the P electrode 111a (e.g., the upper portion or the first electrode). The first protection element 11a may have a first surface 113a (e.g., a top surface or an upper surface) and a second surface 114a (e.g., a bottom surface or a lower surface). The second surface 114a is opposite to the first surface 113a. The P electrode 111a is adjacent to the first surface 113a. The N electrode 112a is adjacent to the second surface 114a.

The first conductive element 12a may be a metal block structure or an interconnection via, and may be configured to electrically connect or electrically conduct the first upper conductive circuit 13a of the upper conductive structure 63 and the second lower conductive circuit 24a of the lower conductive structure 64. Thus, the first unit 1a and the second unit 2a are coupled (e.g., electrically coupled) in series. The first conductive element 12a may have a first surface 123a (e.g., a top surface or an upper surface) and a second surface 124a (e.g., a bottom surface or a lower surface) opposite to the first surface 123a.

The first upper conductive circuit 13a is electrically connected to the negative electrode 101a of the first solar cell 10a and the P electrode 111a of the first protection element 11a simultaneously or at the same time. The first lower conductive circuit 14a is electrically connected to the positive electrode 102a of the first solar cell 10a and the N electrode 112a of the first protection element 11a simultaneously or at the same time. Therefore, the first protection element 11a and the first solar cell 10a are coupled in parallel (e.g., “electrically coupled in parallel”, “electrically connected in parallel”, “in-parallel electrical connection”, or “electrically conducted in parallel”).

The first upper conductive circuit 13a may further extend to a position over the first conductive element 12a and may be electrically connected to the first conductive element 12a. Thus, the first upper conductive circuit 13a is electrically connected to the negative electrode 101a of the first solar cell 10a, the P electrode 111a of the first protection element 11a and the first conductive element 12a simultaneously or at the same time. In addition, the first lower conductive circuit 14a may further extend to a position under the conductive element 62a and may be electrically connected to the conductive element 62a. Thus, the first lower conductive circuit 14a is electrically connected to the positive electrode 102a of the first solar cell 10a, the N electrode 112a of the first protection element 11a and the conductive element 62a simultaneously or at the same time. Thus, the first conductive element 12a may be electrically connected to the first electrode (e.g., the negative electrode 101a) of the first solar cell 10a and the first electrode (e.g., the P electrode 111a) of the first protection element 11a through the first upper conductive circuit 13a directly, and may be not electrically connected to the second electrode (e.g., the positive electrode 102a) of the first solar cell 10a and the second electrode (e.g., the N electrode 112a) of the first protection element 11a directly.

The second solar cell 20a may include a negative electrode 201a (e.g., an upper portion or a first electrode) and a positive electrode 202a (e.g., a lower portion or a second electrode). The positive electrode 202a (e.g., the lower portion or the second electrode) is opposite to the negative electrode 201a (e.g., the upper portion or the first electrode). The second solar cell 20a may have a first surface 203a (e.g., a top surface or an upper surface) and a second surface 204a (e.g., a bottom surface or a lower surface). The second surface 204a is opposite to the first surface 203a. The negative electrode 201a is adjacent to the first surface 203a. The positive electrode 202a is adjacent to the second surface 204a.

The second protection element 21a may be disposed between the second solar cell 20a and the second conductive element 22a. The second protection element 21a may be configured to provide a by-pass circuit, so as to protect the second solar cell 20a. The second protection element 21a may be a diode element, and may include a P electrode 211a (e.g., an upper portion or a first electrode) and an N electrode 212a (e.g., a lower portion or a second electrode). The N electrode 212a (e.g., the lower portion or the second electrode) is opposite to the P electrode 211a (e.g., the upper portion or the first electrode). The second protection element 21a may have a first surface 213a (e.g., a top surface or an upper surface) and a second surface 214a (e.g., a bottom surface or a lower surface). The second surface 214a is opposite to the first surface 213a. The P electrode 211a is adjacent to the first surface 213a. The N electrode 212a is adjacent to the second surface 214a.

The second conductive element 22a may be a metal block structure or an interconnection via, and may be configured to electrically connect or electrically conduct the second upper conductive circuit 23a of the upper conductive structure 63 and the third lower conductive circuit 34a of the lower conductive structure 64. Thus, the second unit 2a and the third unit 3a are coupled (e.g., electrically coupled) in series. The second conductive element 22a may have a first surface 223a (e.g., a top surface or an upper surface) and a second surface 224a (e.g., a bottom surface or a lower surface) opposite to the first surface 223a.

The second upper conductive circuit 23a and the first upper conductive circuit 13a are spaced apart from each other, and they are the segments that independent from each other. That is, the second upper conductive circuit 23a does not directly connect to the first upper conductive circuit 13a. The second lower conductive circuit 24a and the first lower conductive circuit 14a are spaced apart from each other, and they are the segments that independent from each other. That is, the second lower conductive circuit 24a does not directly connect to the first lower conductive circuit 14a. The second upper conductive circuit 23a is electrically connected to the negative electrode 201a of the second solar cell 20a and the P electrode 211a of the second protection element 21a simultaneously or at the same time. The second lower conductive circuit 24a is electrically connected to the positive electrode 202a of the second solar cell 20a and the N electrode 212a of the second protection element 21a simultaneously or at the same time. Therefore, the second protection element 21a and the second solar cell 20a are coupled in parallel (e.g., “electrically coupled in parallel”, “electrically connected in parallel”, “in-parallel electrical connection”, or “electrically conducted in parallel”).

The second upper conductive circuit 23a may further extend to a position over the second conductive element 22a and may be electrically connected to the second conductive element 22a. Thus, the second upper conductive circuit 23a is electrically connected to the negative electrode 201a of the second solar cell 20a, the P electrode 211a of the second protection element 21a and the second conductive element 22a simultaneously or at the same time. In addition, the second lower conductive circuit 24a may further extend to a position under the first conductive element 12a and may be electrically connected to the first conductive element 12a. Thus, the second lower conductive circuit 24a is electrically connected to the positive electrode 202a of the second solar cell 20a, the N electrode 212a of the second protection element 21a and the first conductive element 12a simultaneously or at the same time. Thus, the second conductive element 22a may be electrically connected to the first electrode (e.g., the negative electrode 201a) of the second solar cell 20a and the first electrode (e.g., the P electrode 211a) of the second protection element 21a through the second upper conductive circuit 23a directly, and may be not electrically connected to the second electrode (e.g., the positive electrode 202a) of the second solar cell 20a and the second electrode (e.g., the N electrode 212a) of the second protection element 21a directly. Further, the first conductive element 12a may be electrically connected to the second electrode (e.g., the positive electrode 202a) of the second solar cell 20a and the second electrode (e.g., the N electrode 212a) of the second protection element 21a through the second lower conductive circuit 24a directly.

As shown in FIG. 7 and FIG. 8, the material of the upper transparent protection portion 56 may be different from the material of the main protection portion 55. Alternatively, the upper transparent protection portion 56 and the main protection portion 55 may be formed at different manufacturing processes. Thus, there may be a visible interface or an obvious interface (e.g., the first surface 553 of the main protection portion 55) formed between the upper transparent protection portion 56 and the main protection portion 55. In addition, the material of the lower transparent protection portion 57 may be different from the material of the main protection portion 55. Alternatively, the lower transparent protection portion 57 and the main protection portion 55 may be formed at different manufacturing processes. Thus, there may be a visible interface or an obvious interface (e.g., the second surface 554 of the main protection portion 55) formed between the lower transparent protection portion 57 and the main protection portion 55.

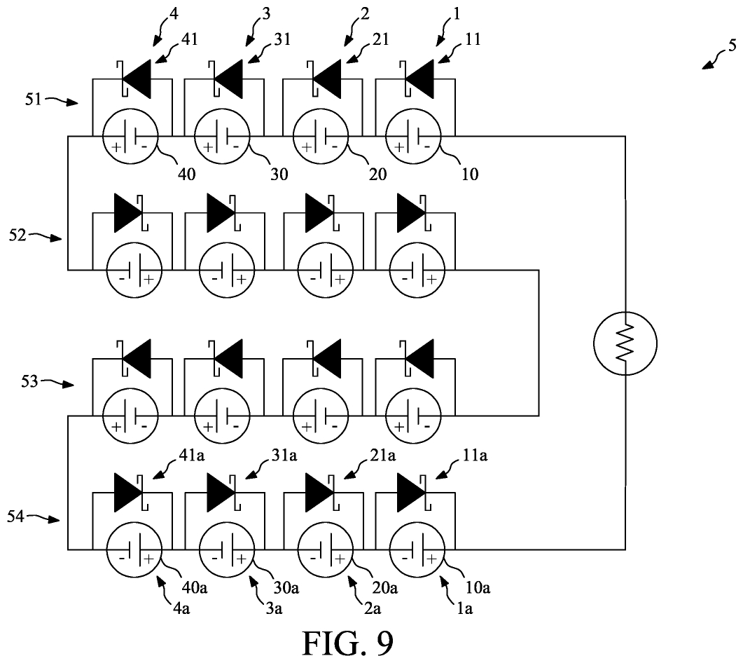

FIG. 9 is a schematic electrical circuit diagram of the solar cell module 5 of FIG. 1. As shown in FIG. 9, all of the rows are coupled (e.g., electrically coupled) in series with one another. In each of the rows, all of the units are coupled in series with one another. In each of the units, the solar cell and the protection element are coupled in parallel. For example, the first row 51, the second row 52, the third row 53 and the fourth row 54 are coupled in series with one another. In the first row 51, the first unit 1, the second unit 2, the third unit 3 and the fourth unit 4 are coupled in series with one another. In the first unit 1, the first solar cell 10 and the first protection element 11 are coupled in parallel.

Due to the design of the present disclosure, when one or some solar cells in the solar cell module 5 are blocked by foreign objects or blocked by shadows, or are damaged and cannot operate normally, it will not cause the entire solar cell module 5 does not work properly. That is, the abnormality of one or some solar cells in the solar cell module 5 will not render the entire solar cell module 5 inoperative. The reason is as follows. When one or some solar cells cannot operate normally, the current will flow through the corresponding protection element without interruption. Therefore, the solar cell module 5 can still generate electricity normally, but the power generation efficiency is slightly reduced. Meanwhile, the hot spot effect may be avoided. In addition, in the present disclosure, both of the upper conductive structure 63 and the lower conductive structure 64 include a redistribution layer (RDL) or a conductive segment and are formed by an electroplating process, thereby simplifying the manufacturing process of the solar cell module 5, and simplifying the installation procedure of the solar cell module 5.

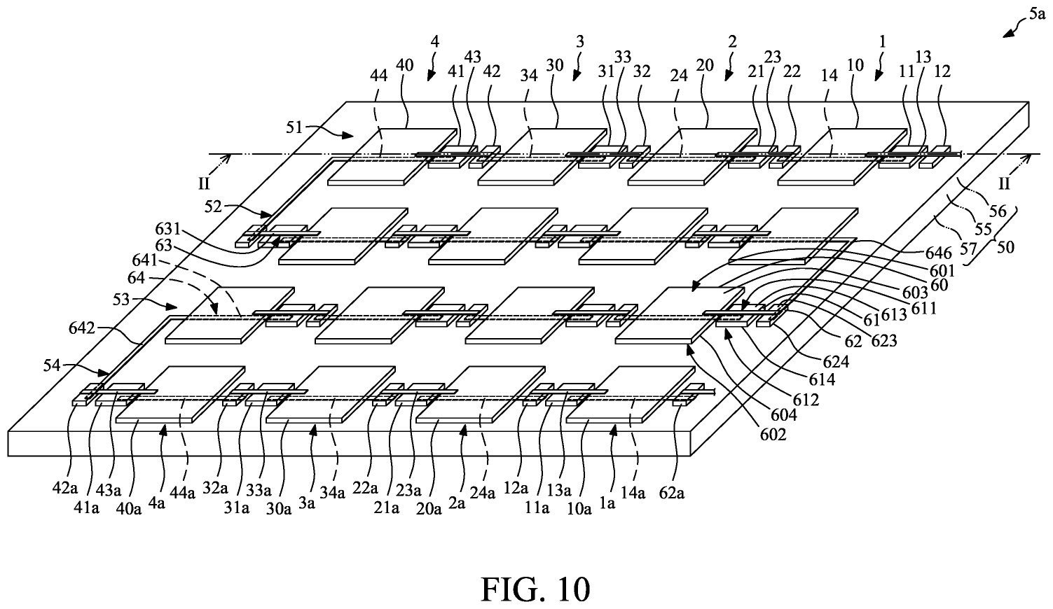

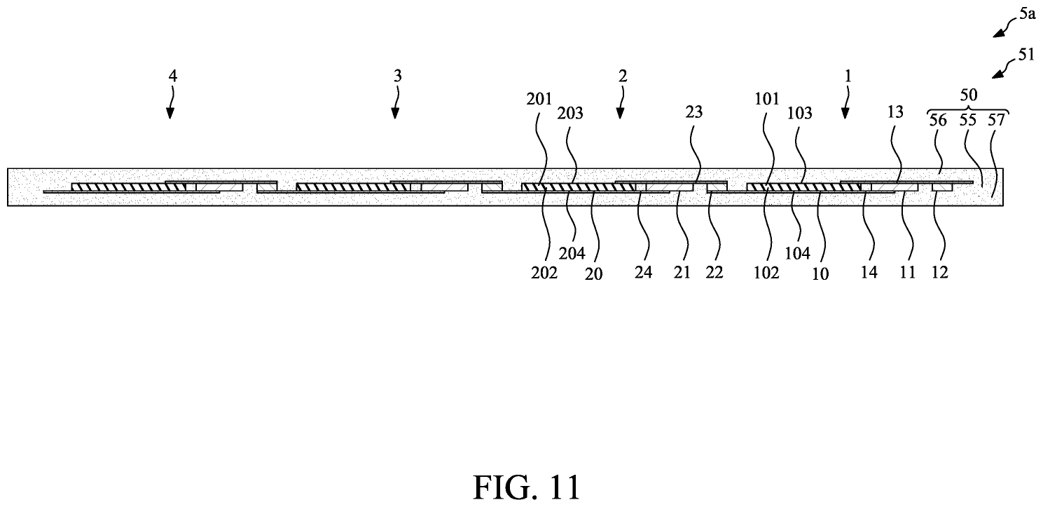

FIG. 10 is a perspective top view of a solar cell module 5a according to one embodiment of the disclosure. FIG. 11 is a cross-sectional view taken along a line II-II on the solar cell module 5a of FIG. 10. The solar cell module 5a of FIG. 10 and FIG. 11 is substantially same as or similar to the solar cell module 5 of FIG. 1 to FIG. 8, and the differences are described as follows. The material of the upper transparent protection portion 56 may be same as the material of the main protection portion 55. Thus, there may be no obvious interface or visible interface between the upper transparent protection portion 56 and the main protection portion 55. That is, the first surface 553 of the main protection portion 55 of FIG. 1 to FIG. 8 does not actually exist. In addition, the material of the lower transparent protection portion 57 may be same as the material of the main protection portion 55. Thus, there may be no obvious interface or visible interface between the lower transparent protection portion 57 and the main protection portion 55. That is, the second surface 554 of the main protection portion 55 of FIG. 1 to FIG. 8 does not actually exist. Therefore, the upper transparent protection portion 56, the main protection portion 55 and the lower transparent protection portion 57 may be integrally formed as an encapsulant 50. The encapsulant 50 may be a one-piece structure or a monolithic structure. In one embodiment, the encapsulant 50 may include a dielectric material or an insulation material. In one embodiment, the encapsulant 50 may include a transparent material, such as ethylene-vinyl acetate copolymer (EVA).

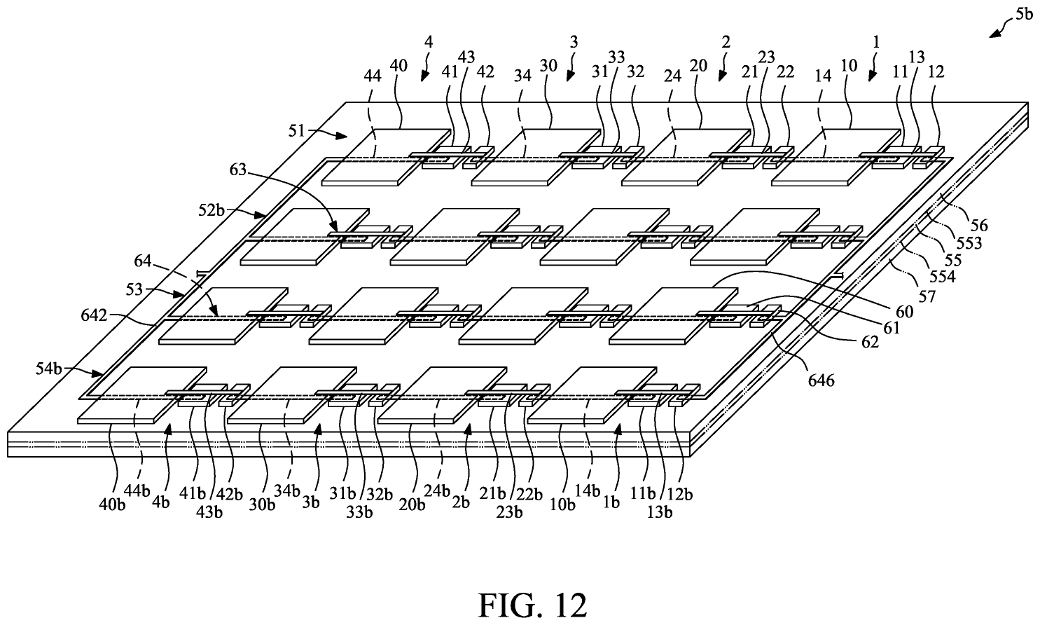

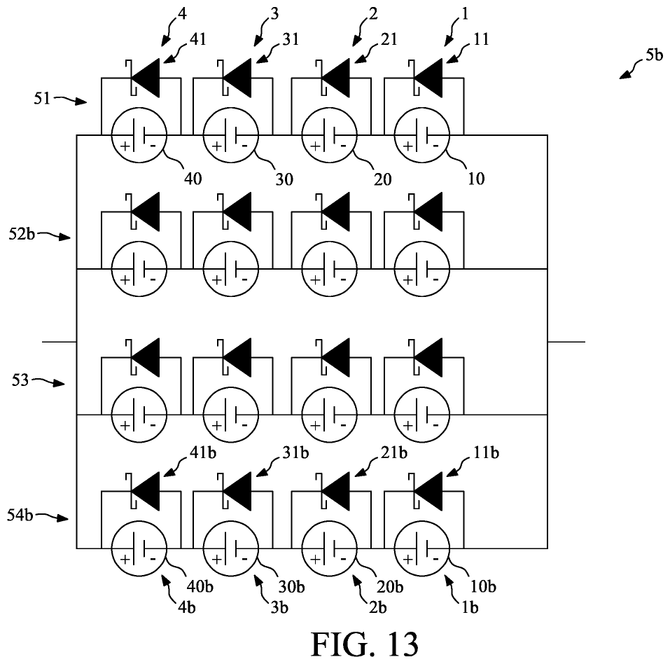

FIG. 12 is a perspective top view of a solar cell module 5b according to one embodiment of the disclosure. FIG. 13 is a schematic electrical circuit diagram of the solar cell module 5b of FIG. 12. The solar cell module 5b of FIG. 12 and FIG. 13 is substantially same as or similar to the solar cell module 5 of FIG. 1 to FIG. 8, and the differences are described as follows. The solar cell module 5b may include a first row 51, a second row 52b, a third row 53 and a fourth row 54b. The arrangements of components in all of the rows (e.g., the first row 51, the second row 52b, the third row 53 and the fourth row 54b) may be the same as each other. For example, the arrangement of components in the first row 51 is the same as the arrangement of components in the second row 52b. The arrangement of components in the first row 51 is the same as the arrangement of components in the third row 53. The arrangement of components in the first row 51 is the same as the arrangement of components in the fourth row 54b.

In one embodiment, the arrangement of components in the first row 51 of FIG. 12 is the same as the arrangement of components in the first row 51 of FIG. 1. In one embodiment, the fourth row 54b of FIG. 12 may include a first solar cell 10b, a second solar cell 20b, a third solar cell 30b, a fourth solar cell 40b, a first protection element 11b, a second protection element 21b, a third protection element 31b, a fourth protection element 41b, a first conductive element 12b, a second conductive element 22b, a third conductive element 32b and a fourth conductive element 42b. The upper conductive structure 63 may include a first upper conductive circuit 13b, a second upper conductive circuit 23b, a third upper conductive circuit 33b and a fourth upper conductive circuit 43b. The lower conductive structure 64 may include a first lower conductive circuit 14b, a second lower conductive circuit 24b, a third lower conductive circuit 34b and a fourth lower conductive circuit 44b.

For example, the first solar cell 10b, the first protection element 11b and the first conductive element 12b form a first unit 1b. The second solar cell 20b, the second protection element 21b and the second conductive element 22b form a second unit 2b. The third solar cell 30b, the third protection element 31b and the third conductive element 32b form a third unit 3b. The fourth solar cell 40b, the fourth protection element 41b and the fourth conductive element 42b form a fourth unit 4b. The arrangements of components in the first unit 1b, the second unit 2b, the third unit 3b and the fourth unit 4b of the fourth row 54b are the same as the arrangements of components in the first unit 1, the second unit 2, the third unit 3 and the fourth unit 4 of the first row 51, respectively.

In addition, the at least one lower connecting segment 642, 646 may be configured to electrically connect different rows (e.g., the first row 51, the second row 52b, the third row 53 and the fourth row 54b), so as to electrically couple the rows 51, 52b, 53, 54 in parallel.

As shown in FIG. 13, the rows 51, 52b, 53, 54 may be electrically coupled in parallel. In each of the rows, all of the units are coupled in series with one another. In each of the units, the solar cell and the protection element are coupled in parallel.

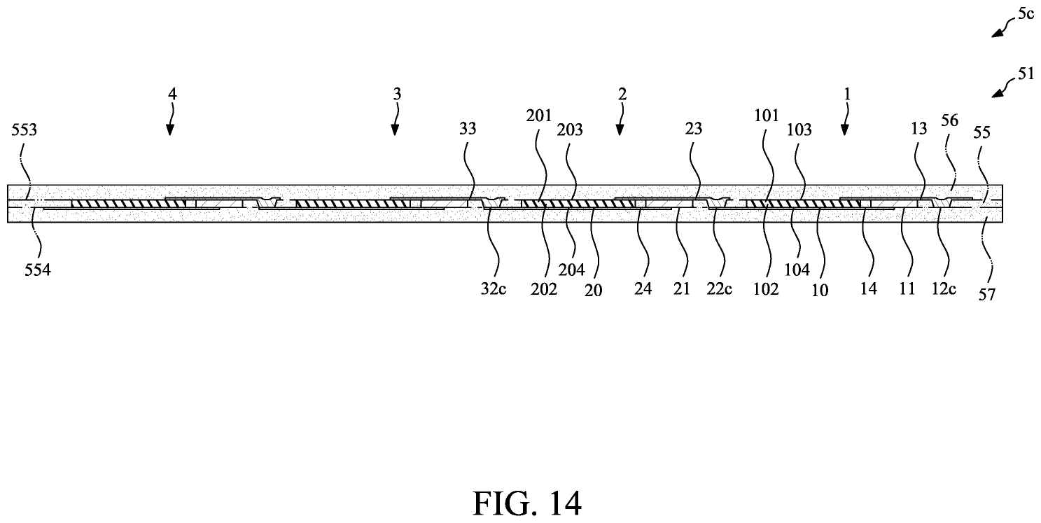

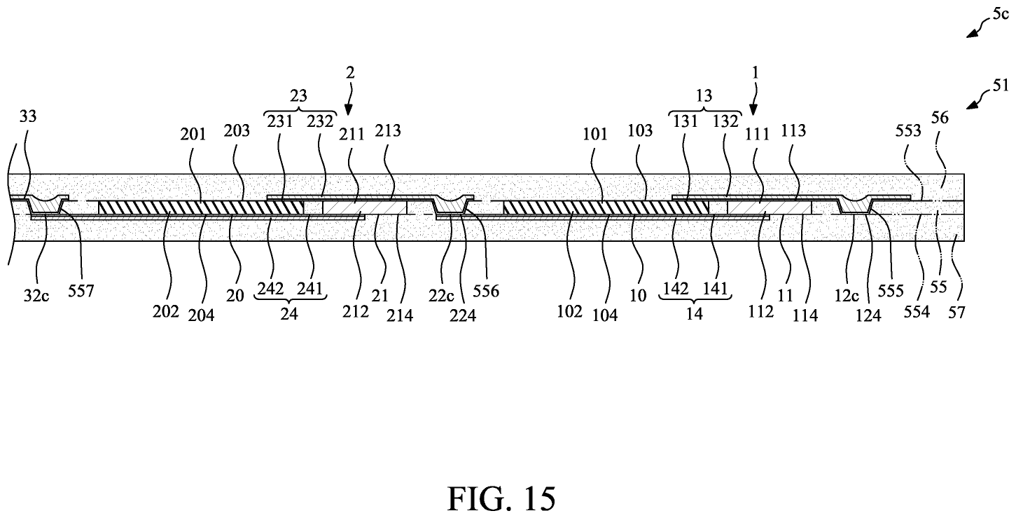

FIG. 14 is a cross-sectional view of a solar cell module 5c according to one embodiment of the disclosure. FIG. 15 is a partially enlarged view of the solar cell module 5c of FIG. 14. The solar cell module 5c of FIG. 14 and FIG. 15 is substantially same as or similar to the solar cell module 5 of FIG. 1 to FIG. 8, except that the structure of the conductive element is an interconnection via. For example, the structure of the first conductive element 12c may be a first interconnection via adjacent to the first protection element 11, and extending through the main protection portion 55. The first conductive element 12c may extend from the first surface 553 of the main protection portion 55 to the second surface 554 of the main protection portion 55. The first conductive element 12c may be disposed in a first through hole 555 of the main protection portion 55, and may include a seed layer 131 and a conductive material 132 disposed on the seed layer 131. The first upper conductive circuit 13 and the first conductive element 12c (e.g., the first interconnection via) may be formed concurrently and integrally.

For example, the structure of the second conductive element 22c may be a second interconnection via adjacent to the second protection element 21, and extending through the main protection portion 55. The second conductive element 22c may extend from the first surface 553 of the main protection portion 55 to the second surface 554 of the main protection portion 55. The second conductive element 22c may be disposed in a second through hole 556 of the main protection portion 55, and may include a seed layer 231 and a conductive material 232 disposed on the seed layer 231. The second upper conductive circuit 23 and the second conductive element 22c (e.g., the second interconnection via) may be formed concurrently and integrally.

For example, the structure of the third conductive element 32c may be a third interconnection via extending through the main protection portion 55. The third conductive element 32c may extend from the first surface 553 of the main protection portion 55 to the second surface 554 of the main protection portion 55. The third conductive element 32c may be disposed in a third through hole 557 of the main protection portion 55. The third upper conductive circuit 33 and the third conductive element 32c (e.g., the third interconnection via) may be formed concurrently and integrally.

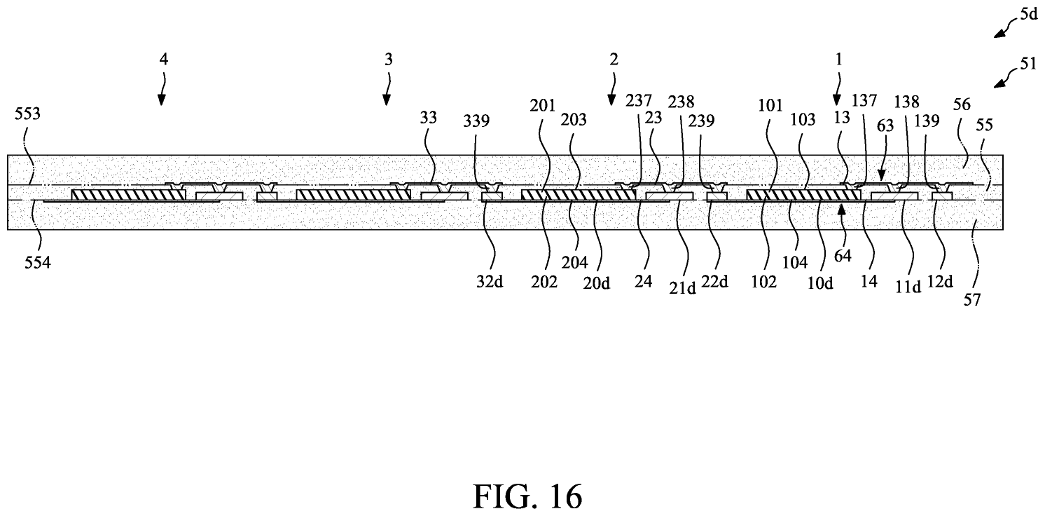

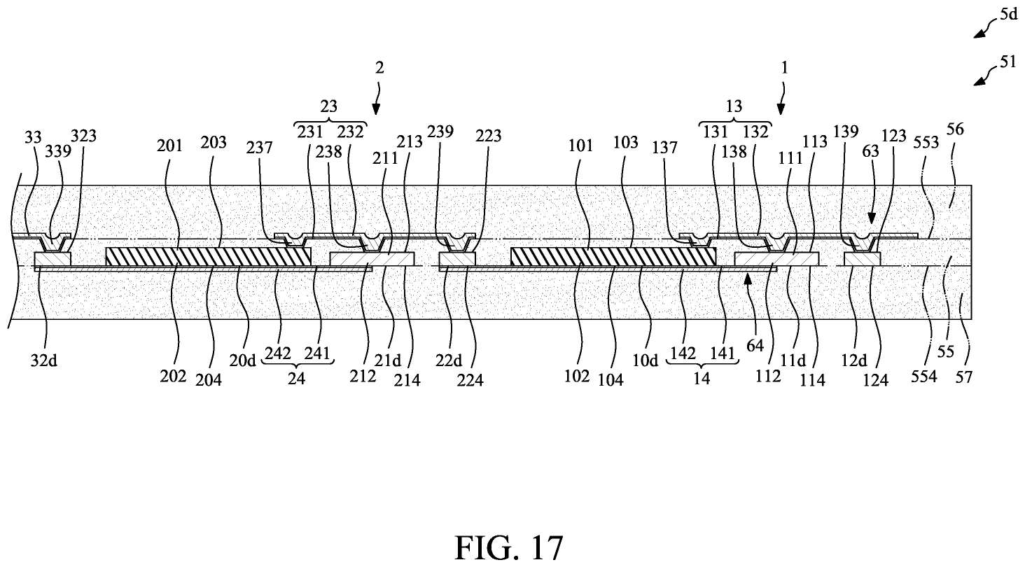

FIG. 16 is a cross-sectional view of a solar cell module 5d according to one embodiment of the disclosure. FIG. 17 is a partially enlarged view of the solar cell module 5d of FIG. 16. The solar cell module 5d of FIG. 16 and FIG. 17 is substantially same as or similar to the solar cell module 5 of FIG. 1 to FIG. 8, and the differences are described as follows.

The thickness of the solar cell (e.g., the first solar cell 10d and the second solar cell 20d), the thickness of the protection element (e.g., the first protection element 11d and the second protection element 21d) and the thickness of the conductive element (e.g., the first conductive element 12d, the second conductive element 22d and the third conductive element 32d) may be less than the thickness of the main protection portion 55. The thickness of the solar cell (e.g., the first solar cell 10d and the second solar cell 20d), the thickness of the protection element (e.g., the first protection element 11d and the second protection element 21d) and the thickness of the conductive element (e.g., the first conductive element 12d, the second conductive element 22d and the third conductive element 32d) may be different from each other. For example, the thickness of the solar cell (e.g., the first solar cell 10d and the second solar cell 20d) may be greater than the thickness of the protection element (e.g., the first protection element 11d and the second protection element 21d) and the thickness of the conductive element (e.g., the first conductive element 12d, the second conductive element 22d and the third conductive element 32d).

Thus, the first surface 553 of the main protection portion 55 may be higher than the first surface of the solar cell (e.g., the first surface 103 (top surface) of the first solar cell 10d and the first surface 203 (top surface) of the second solar cell 20d), the first surface of the protection element (e.g., the first surface 113 (top surface) of the first protection element 11d and the first surface 213 (top surface) of the second protection element 21d) and the first surface of the conductive element (e.g., the first surface 123 (top surface) of the first conductive element 12d, the first surface 223 (top surface) of the second conductive element 22d and the first surface 323 (top surface) of the third conductive element 32d). In other words, the main protection portion 55 may cover the first surface of the solar cell (e.g., the first surface 103 (top surface) of the first solar cell 10d and the first surface 203 (top surface) of the second solar cell 20d), the first surface of the protection element (e.g., the first surface 113 (top surface) of the first protection element 11d and the first surface 213 (top surface) of the second protection element 21d) and the first surface of the conductive element (e.g., the first surface 123 (top surface) of the first conductive element 12d, the first surface 223 (top surface) of the second conductive element 22d and the first surface 323 (top surface) of the third conductive element 32d).

The upper conductive circuits 13, 23 of the upper conductive structure 63 may be disposed on the first surface 553 of the main protection portion 55, and may be spaced apart from the solar cell (e.g., the first solar cell 10d and the second solar cell 20d), the protection element (e.g., the first protection element 11d and the second protection element 21d) and the conductive element (e.g., the first conductive element 12d, the second conductive element 22d and the third conductive element 32d). The upper conductive circuits 13, 23 of the upper conductive structure 63 may be not directly contact the solar cell (e.g., the first solar cell 10d and the second solar cell 20d), the protection element (e.g., the first protection element 11d and the second protection element 21d) and the conductive element (e.g., the first conductive element 12d, the second conductive element 22d and the third conductive element 32d).

The upper conductive structure 63 may further include a plurality of upper conductive vias 137, 138, 139, 237, 238, 239, 339. The upper conductive vias 137, 138, 139, 237, 238, 239, 339 may extend through a plurality of portions of the main protection portion 55 that are disposed on the solar cells 10d, 20d and the protection elements 11d, 21d, and may electrically connect the upper conductive circuits 13, 23 to the first surfaces 103, 203 (top surfaces) of the solar cells 10d, 20d and the first surfaces 113, 213 (top surfaces) of the protection elements 11d, 21d. For example, the upper conductive via 137 may extend through a portion of the main protection portion 55 that is disposed on the first solar cell 10d, and may electrically connect the first upper conductive circuit 13 and the first surface 103 (top surface) of the first solar cell 10d. The upper conductive via 138 may extend through a portion of the main protection portion 55 that is disposed on the first protection element 11d, and may electrically connect the first upper conductive circuit 13 and the first surface 113 (top surface) of the first protection element 11d. The upper conductive via 139 may extend through a portion of the main protection portion 55 that is disposed on the first conductive element 12d, and may electrically connect the first upper conductive circuits 13 and the first surface 123 (top surface) of the first conductive element 12d.

Similarly, the upper conductive via 237 may extend through a portion of the main protection portion 55 that is disposed on the second solar cell 20d, and may electrically connect the second upper conductive circuit 23 and the first surface 203 (top surface) of the second solar cell 20d. The upper conductive via 238 may extend through a portion of the main protection portion 55 that is disposed on the second protection element 21d, and may electrically connect the second upper conductive circuit 23 and the first surface 213 (top surface) of the second protection element 21d. The upper conductive via 239 may extend through a portion of the main protection portion 55 that is disposed on the second conductive element 22d, and may electrically connect the second upper conductive circuits 23 and the first surface 223 (top surface) of the second conductive element 22d. The upper conductive via 339 may extend through a portion of the main protection portion 55 that is disposed on the third conductive element 32d, and may electrically connect the third upper conductive circuits 33 and the first surface 323 (top surface) of the third conductive element 32d.

In one embodiment, the first upper conductive circuit 13 and the upper conductive vias 137, 138, 139 may be formed concurrently and integrally. The second upper conductive circuit 23 and the upper conductive vias 237, 238, 239 may be formed concurrently and integrally. The third upper conductive circuit 33 and the upper conductive via 339 may be formed concurrently and integrally. The upper conductive vias 137, 138, 139 may include a seed layer 131 and a conductive material 132 disposed on the seed layer 131. The upper conductive vias 237, 238, 239 may include a seed layer 231 and a conductive material 232 disposed on the seed layer 231.

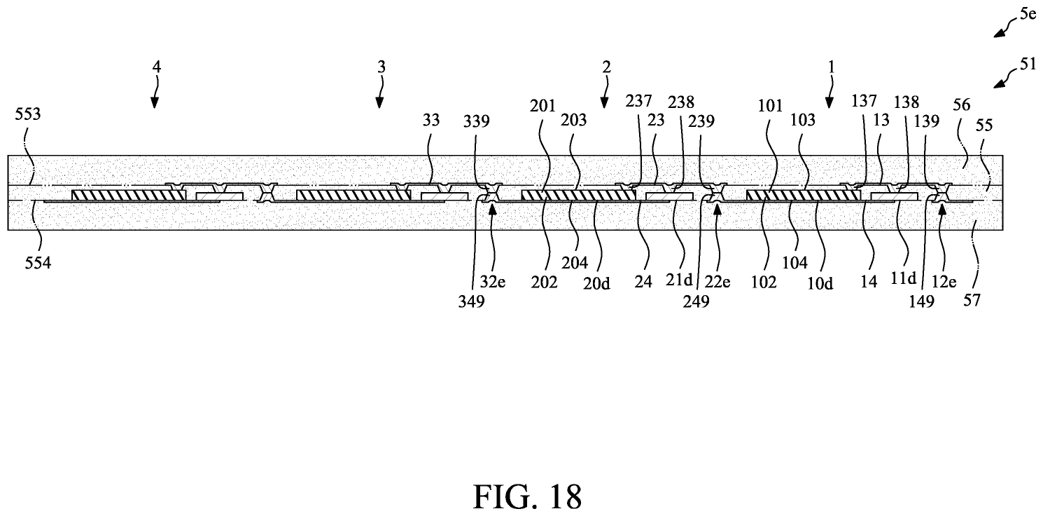

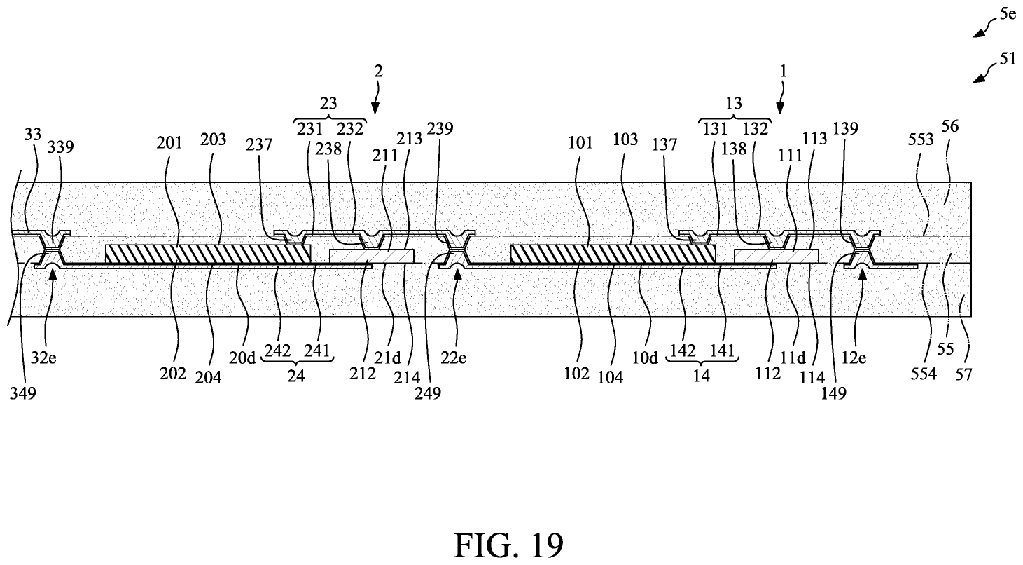

FIG. 18 is a cross-sectional view of a solar cell module 5e according to one embodiment of the disclosure. FIG. 19 is a partially enlarged view of the solar cell module 5e of FIG. 18. The solar cell module 5e of FIG. 18 and FIG. 19 is substantially same as or similar to the solar cell module 5e of FIG. 16 and FIG. 17, and the differences are described as follows. As shown in FIG. 18 and FIG. 19, the conductive elements 12e, 22e, 32e are conductive via structures. For example, the first conductive elements 12e may be a lower conductive via 149 that contacts the upper conductive via 139. The lower conductive via 149 may taper upward. The upper conductive via 139 may taper downward. Alternatively, the lower conductive via 149 and the upper conductive via 139 may collectively form a conductive element. Further, the second conductive elements 22e may be a lower conductive via 249 that contacts the upper conductive via 239. The lower conductive via 249 and the first lower conductive circuit 14 may be formed concurrently and integrally. The lower conductive via 249 may include the seed layer 141 and a conductive material 142 disposed on the seed layer 141. The lower conductive via 249 may taper upward. The upper conductive via 239 may taper downward. Alternatively, the lower conductive via 249 and the upper conductive via 239 may collectively form a conductive element. Further, the third conductive elements 32e may be a lower conductive via 349 that contacts the upper conductive via 339. The lower conductive via 349 and the second lower conductive circuit 24 may be formed concurrently and integrally. The lower conductive via 349 may include the seed layer 241 and a conductive material 242 disposed on the seed layer 241. The lower conductive via 349 may taper upward. The upper conductive via 339 may taper downward. Alternatively, the lower conductive via 349 and the upper conductive via 339 may collectively form a conductive element.

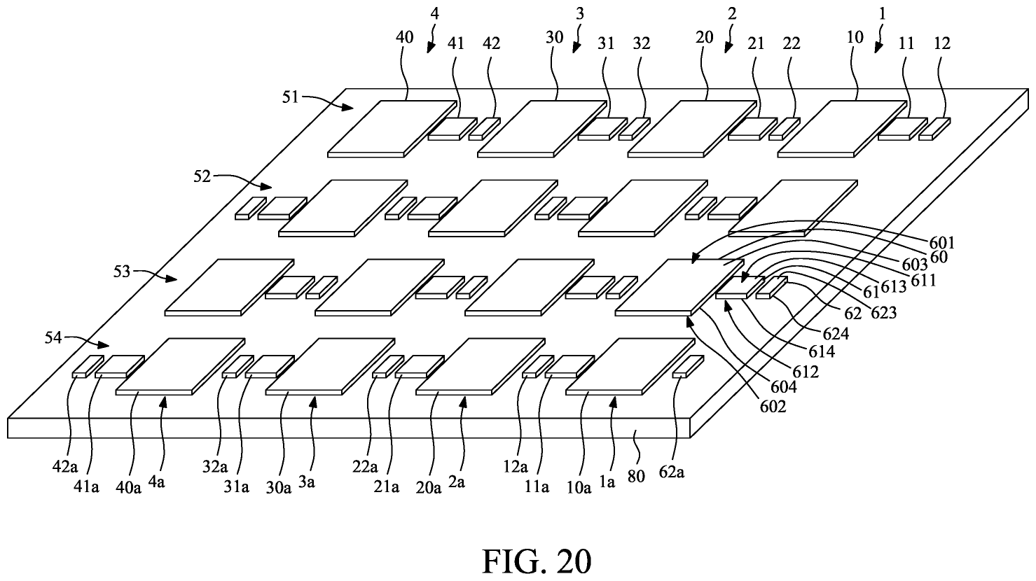

FIG. 20 through FIG. 35 illustrate an example of a method for manufacturing a solar cell module according to some embodiments of the present disclosure. In some embodiments, the method is for manufacturing a solar cell module such as the solar cell module 5 shown in FIG. 1 to FIG. 8.

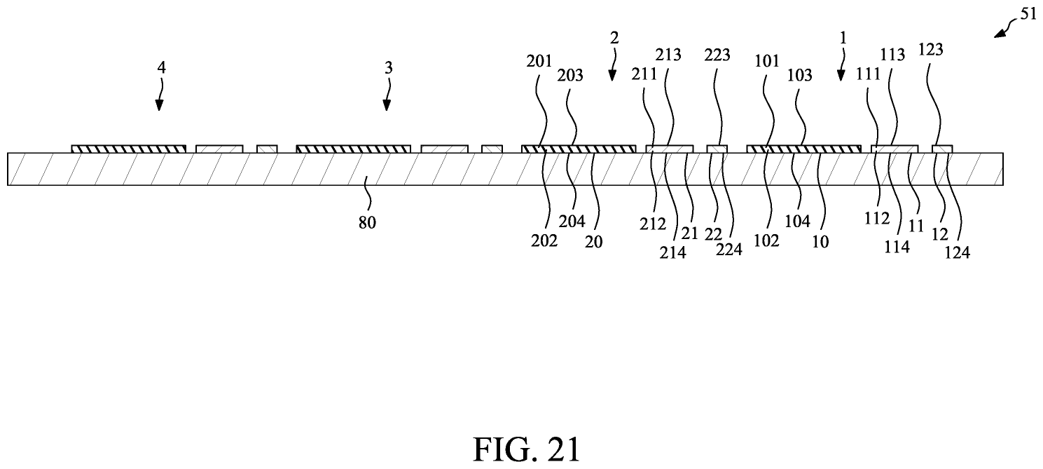

Referring to FIG. 20 and FIG. 21, wherein FIG. 21 is a cross-sectional view of FIG. 20, a plurality of solar cells 60, a plurality of protection elements 61 and a plurality of conductive elements 62 may be disposed on a carrier 80. The solar cells 60, the protection elements 61 and the conductive elements 62 may be the same as the solar cells 60, the protection elements 61 and the conductive elements 62 of FIG. 1, respectively. As shown in FIG. 20 and FIG. 21, the conductive elements 62 may be disposed between the solar cells 60 respectively. That is, there may be one conductive element 62 disposed between adjacent two solar cells 60. In addition, the protection elements 61 may be disposed between the conductive element 62 and the solar cell 60. In one embodiment, the solar cells 60, the protection elements 61 and the conductive elements 62 are arranged in an array. Thus, the solar cells 60, the protection elements 61 and the conductive elements 62 may include a first row 51, a second row 52, a third row 53 and a fourth row 54. The first row 51, the second row 52, the third row 53 and the fourth row 54 of FIG. 20 and FIG. 21 may be the same as the first row 51, the second row 52, the third row 53 and the fourth row 54 of FIG. 1.

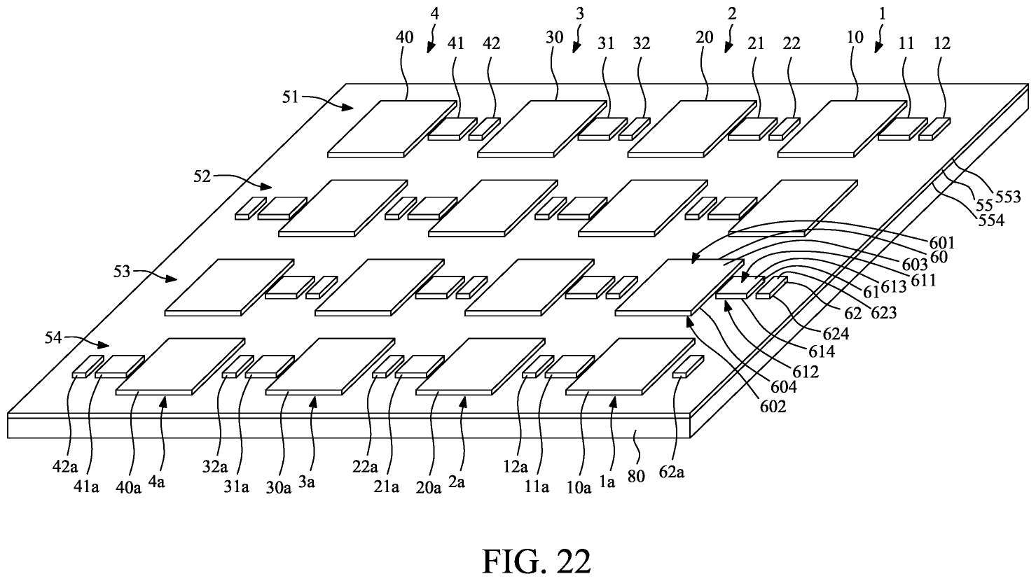

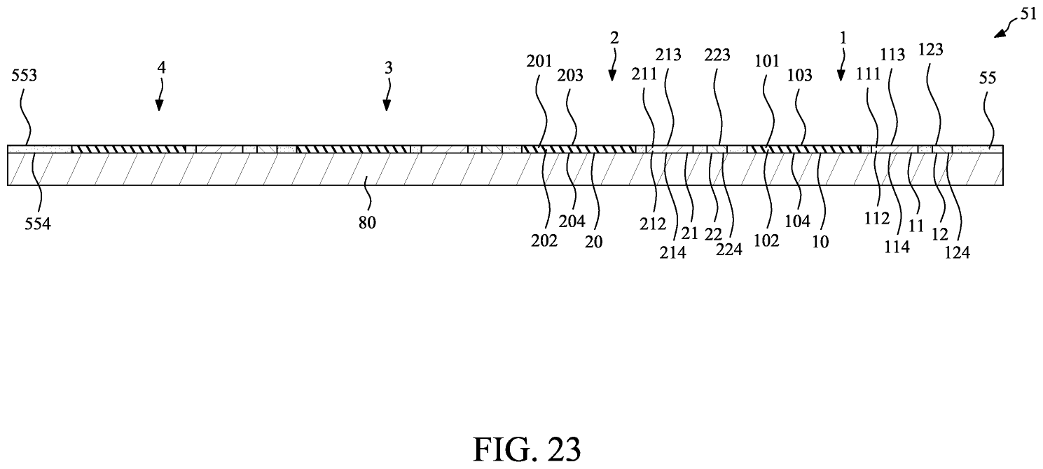

Referring to FIG. 22 and FIG. 23, wherein FIG. 23 is a cross-sectional view of FIG. 22, a main protection portion 55 may be formed to encapsulate the solar cells 60, the protection elements 61 and the conductive elements 62. The main protection portion 55 may be the same as the main protection portion 55 of FIG. 1. In one embodiment, a thickness of the main protection portion 55 may be substantially equal to a thickness of the solar cell 60, a thickness of the protection element 61 and a thickness of the conductive element 62. Thus, a first surface 553 (e.g., a top surface) of the main protection portion 55 may be substantially coplanar with or level with the first surface 603 of the solar cell 60, the first surface 613 of the protection element 61 and the first surface 623 of the conductive element 62. A second surface 554 (e.g., a bottom surface) of the main protection portion 55 may contact the carrier 80, and may be substantially coplanar with or level with the second surface 604 of the solar cell 60, the second surface 614 of the protection element 61 and the second surface 624 of the conductive element 62.

Then, the solar cells 60 and the protection elements 61 may be electrically coupled in parallel and in one-to-one relationships. The solar cells 60 may be electrically coupled with one another. For example, an upper conductive structure 63 and a lower conductive structure 64 may be formed on the first surface 553 (e.g., the top surface) and the second surface 554 (e.g., the bottom surface) of the main protection portion 55, respectively. Thus, the solar cells 60 and the protection elements 61 are electrically coupled (e.g., electrically connected) in parallel, which is described in detail below.

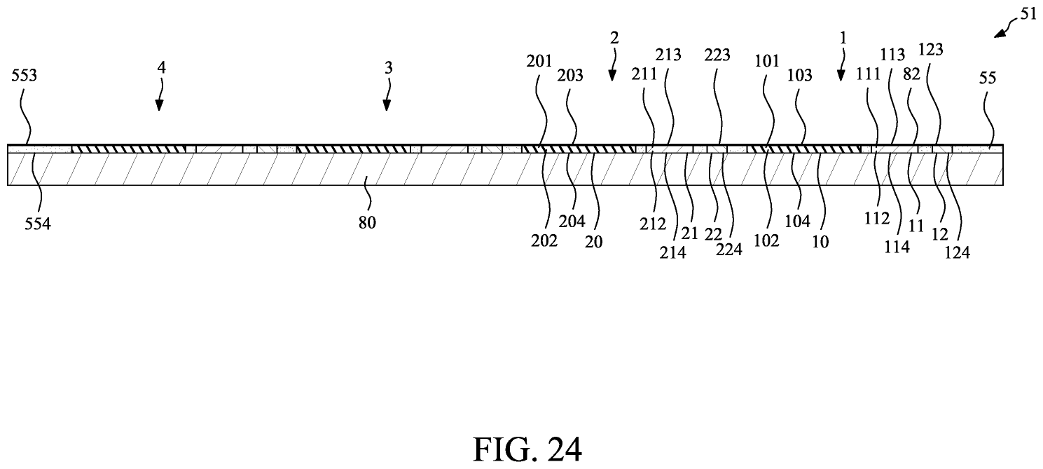

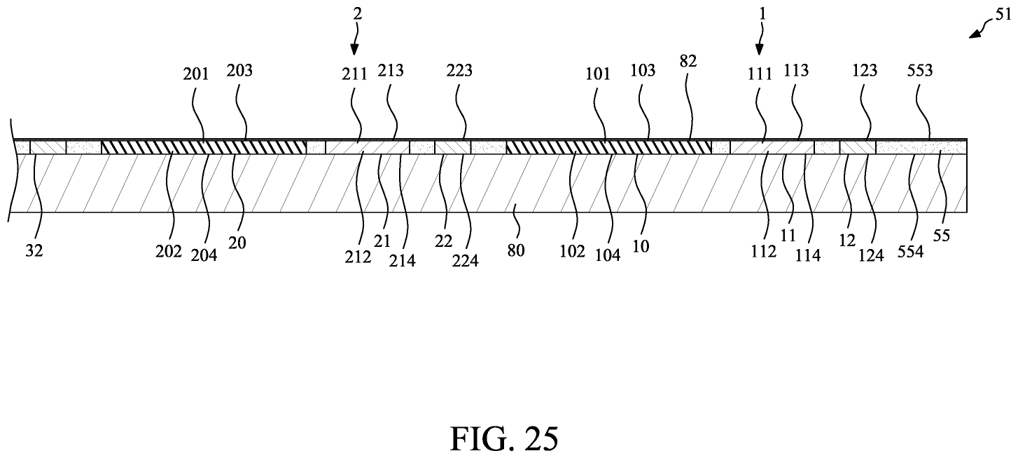

Referring to FIG. 24 and FIG. 25, wherein FIG. 25 is a partially enlarged view of FIG. 24, a seed layer 82 may be formed on the first surface 553 of the main protection portion 55, the first surfaces 103, 203 of the solar cells 10, 20, the first surfaces 113, 213 of the protection elements 11, 21 and the first surfaces 123, 223 of the conductive elements 12, 22 by, for example, electroplating.

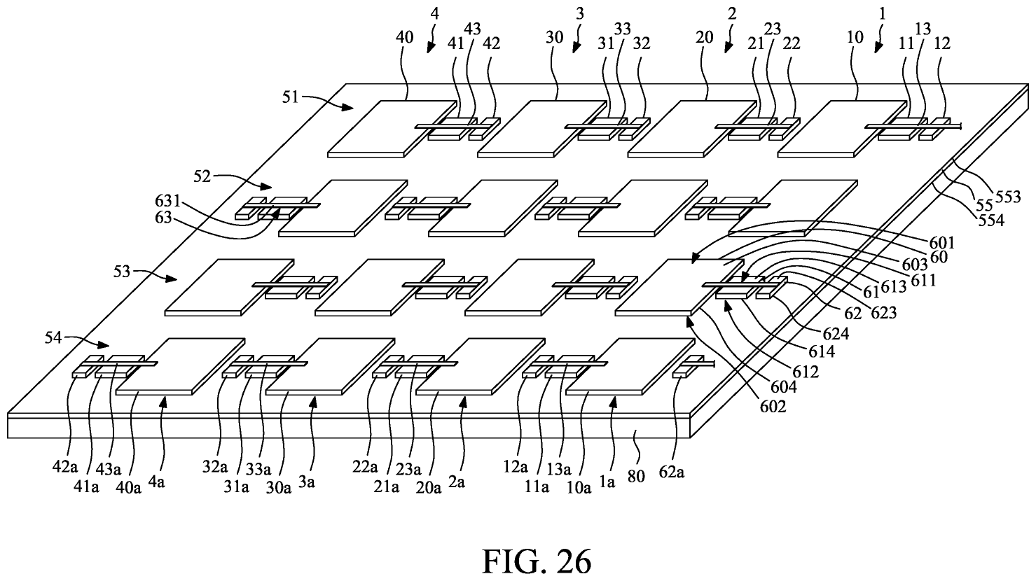

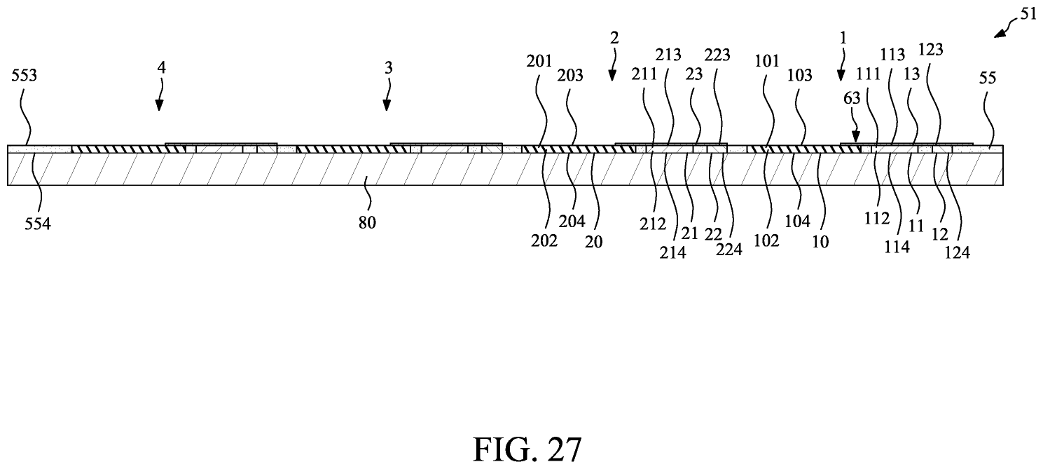

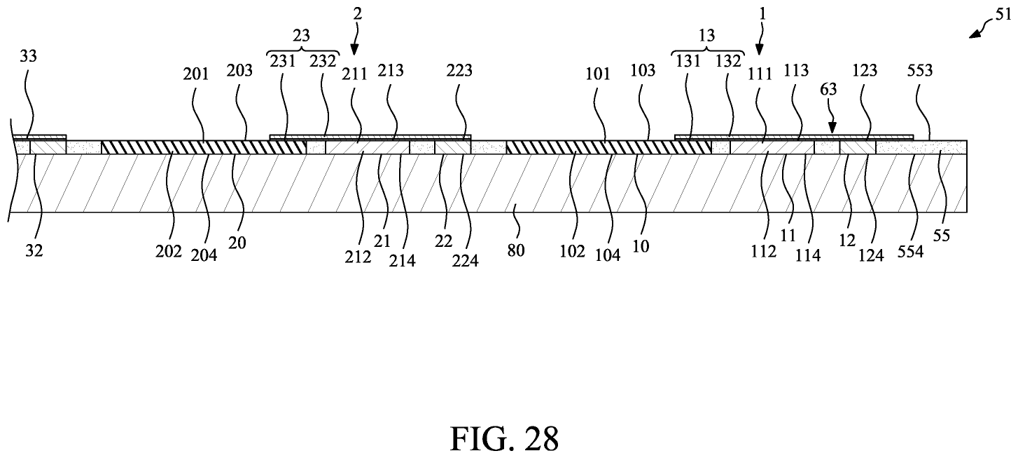

Referring to FIG. 26, FIG. 27 and FIG. 28, wherein FIG. 27 is a cross-sectional view of FIG. 26, FIG. 28 is a partially enlarged view of FIG. 27, a conductive material 132, 232 may be formed on the seed layer 82 by, for example, electroplating. Then, the seed layer 82 may be patterned so as to form the upper conductive structure 63. The patterned seed layer 82 may include, for example, the seed layers 131, 231. The upper conductive structure 63 may include a plurality of upper conductive circuits 631. The upper conductive structure 63 (e.g., the upper conductive circuits 631) may be disposed on the first surface 553 of the main protection portion 55, and may be disposed over the solar cells 60, the protection elements 61 and the conductive elements 62. In one embodiment, the upper conductive structure 63 (e.g., the upper conductive circuits 631) may directly contact and electrically connect the first surface 603 of the solar cell 60, the first surface 613 of the protection element 61 and the first surface 623 of the conductive element 62.

For example, the upper conductive circuits 631 of the upper conductive structure 63 may include a first upper conductive circuit 13, 13a, a second upper conductive circuit 23, 23a, a third upper conductive circuit 33, 33a and a fourth upper conductive circuit 43, 43a. The first upper conductive circuit 13 may include a seed layer 131 and a conductive material 132 disposed on the seed layer 131. The first upper conductive circuit 13 is electrically connected to the negative electrode 101 of the first solar cell 10 and the P electrode 111 of the first protection element 11 simultaneously or at the same time. The first upper conductive circuit 13 may further extend to a position over the first conductive element 12 and may be electrically connected to the first conductive element 12. Thus, the first upper conductive circuit 13 is electrically connected to the negative electrode 101 of the first solar cell 10, the P electrode 111 of the first protection element 11 and the first conductive element 12 simultaneously or at the same time. In addition, the second upper conductive circuit 23 may include a seed layer 231 and a conductive material 232 disposed on the seed layer 231. The second upper conductive circuit 23 is electrically connected to the negative electrode 201 of the second solar cell 20 and the P electrode 211 of the second protection element 21 simultaneously or at the same time. The second upper conductive circuit 23 may further extend to a position over the second conductive element 22 and may be electrically connected to the second conductive element 22. Thus, the second upper conductive circuit 23 is electrically connected to the negative electrode 201 of the second solar cell 20, the P electrode 211 of the second protection element 21 and the second conductive element 22 simultaneously or at the same time.

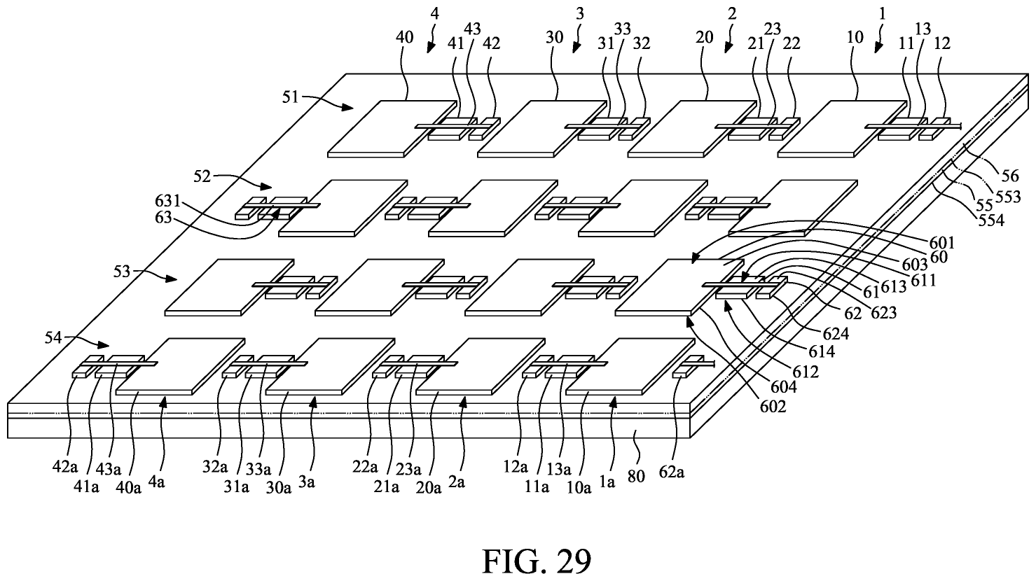

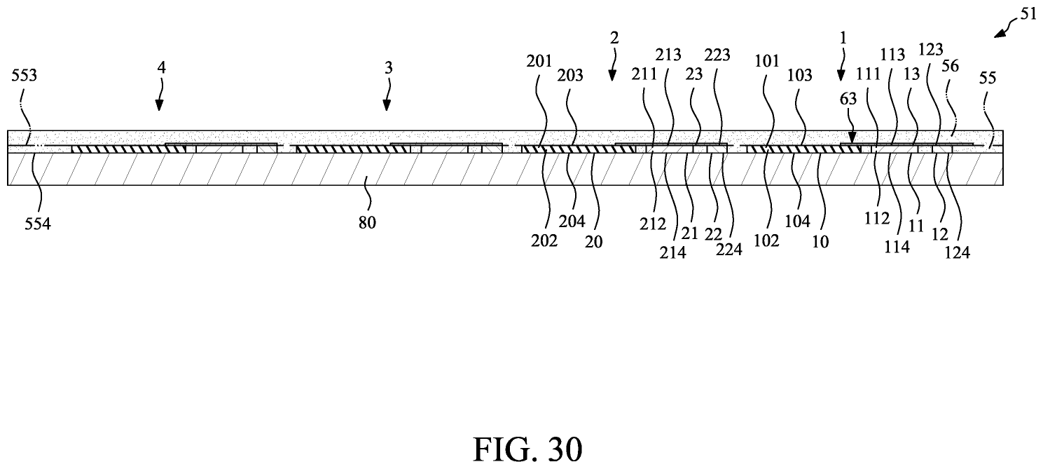

Referring to FIG. 29 and FIG. 30, wherein FIG. 30 is a cross-sectional view of FIG. 29, an upper transparent protection portion 56 may be formed to cover the upper conductive structure 63 and the first surface 553 (e.g., the top surface) of the main protection portion 55. The upper transparent protection portion 56 may be the same as the upper transparent protection portion 56 of FIG. 1.

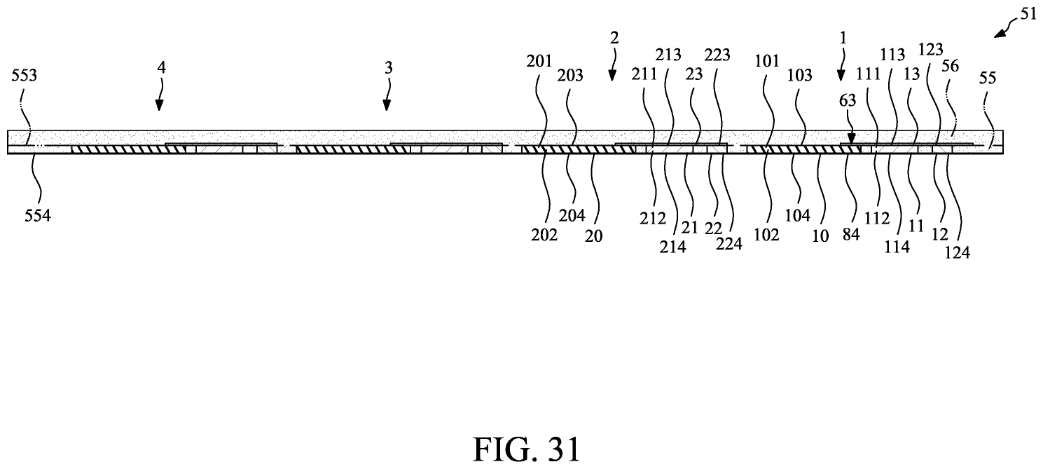

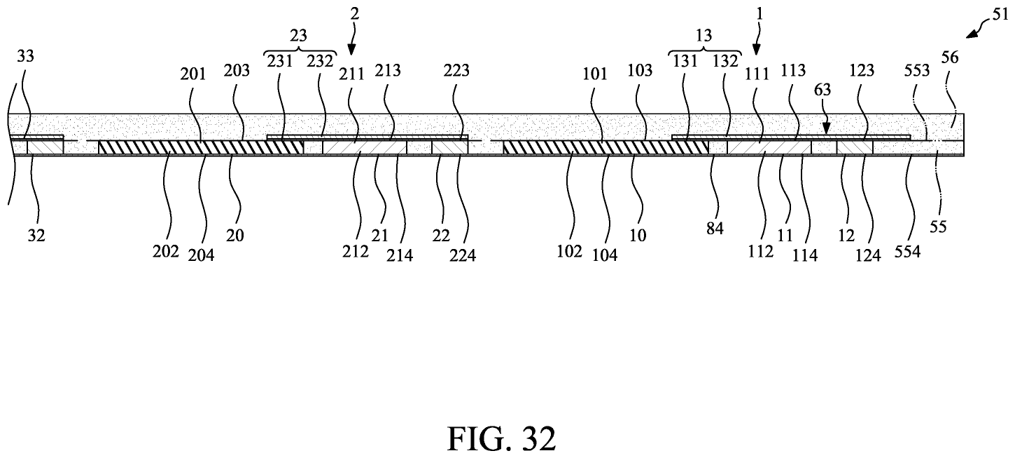

Referring to FIG. 31 and FIG. 32, wherein FIG. 32 is a partially enlarged view of FIG. 31, the carrier 80 may be removed. Then, a seed layer 84 may be formed on the second surface 554 of the main protection portion 55, the second surfaces 104, 204 of the solar cells 10, 20, the second surfaces 114, 214 of the protection elements 11, 21 and the second surfaces 124, 224 of the conductive elements 12, 22 by, for example, electroplating.

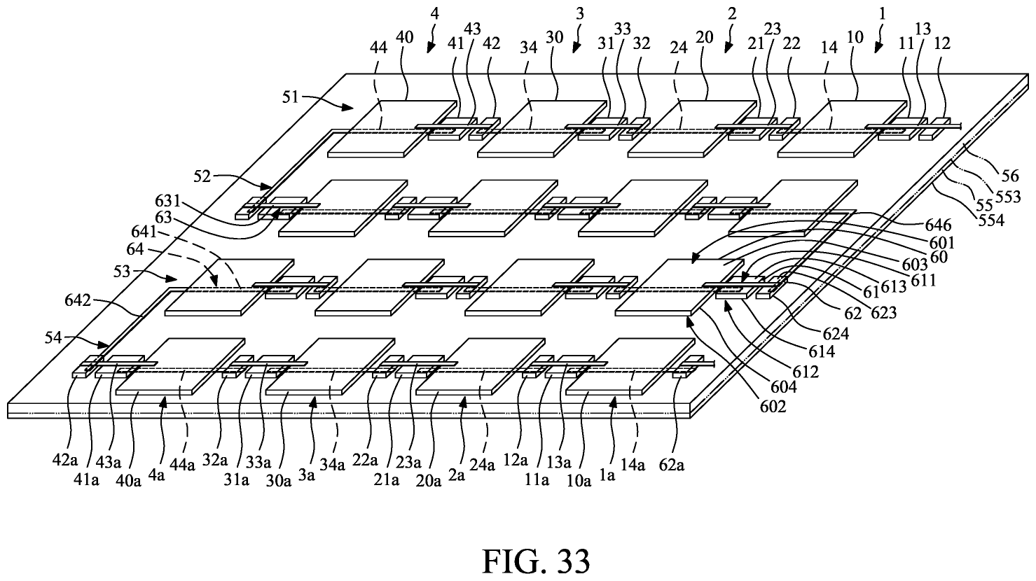

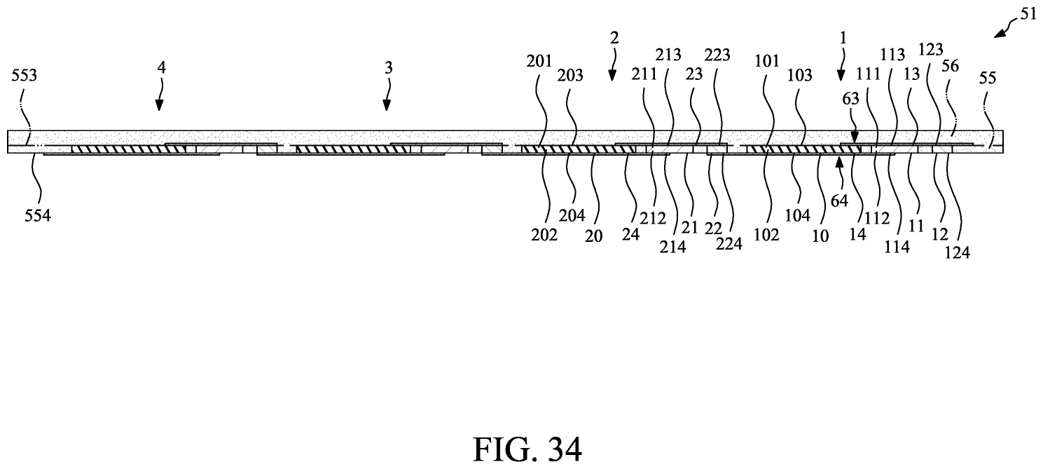

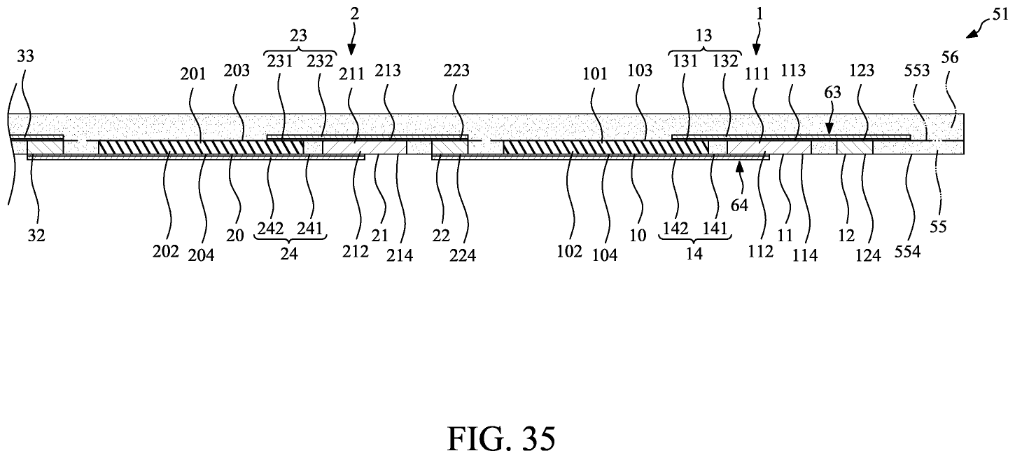

Referring to FIG. 33, FIG. 34 and FIG. 35, wherein FIG. 34 is a cross-sectional view of FIG. 33, FIG. 35 is a partially enlarged view of FIG. 34, a conductive material 142, 242 may be formed on the seed layer 84 by, for example, electroplating. Then, the seed layer 84 may be patterned so as to form the lower conductive structure 64. The patterned seed layer 84 may include, for example, the seed layers 141, 241. The lower conductive structure 64 may include a plurality of lower conductive circuits 641 and at least one lower connecting segment 642, 646.

The lower conductive structure 64 (e.g., the lower conductive circuits 641 and the lower connecting segment 642, 646) may be disposed on the second surface 554 of the main protection portion 55, and may be disposed under the solar cells 60, the protection elements 61 and the conductive elements 62. In one embodiment, the lower conductive structure 64 (e.g., the lower conductive circuits 641) may directly contact and electrically connect the second surface 604 of the solar cell 60, the second surface 614 of the protection element 61 and the second surface 624 of the conductive element 62.

For example, the lower conductive circuits 641 of the lower conductive structure 64 may include a first lower conductive circuit 14, 14a, a second lower conductive circuit 24, 24a, a third lower conductive circuit 34, 34a and a fourth lower conductive circuit 44, 44a. The first lower conductive circuit 14 may include a seed layer 141 and a conductive material 142 disposed on the seed layer 141. The first lower conductive circuit 14 is electrically connected to the positive electrode 102 of the first solar cell 10 and the N electrode 112 of the first protection element 11 simultaneously or at the same time. Therefore, the first protection element 11 and the first solar cell 10 are coupled in parallel (e.g., “electrically coupled in parallel”, “electrically connected in parallel”, “in-parallel electrical connection”, or “electrically conducted in parallel”). The first lower conductive circuit 14 may further extend to a position under the second conductive element 22, and may be electrically connected to the second conductive element 22. Thus, the first lower conductive circuit 14 is electrically connected to the positive electrode 102 of the first solar cell 10, the N electrode 112 of the first protection element 11 and the second conductive element 22 simultaneously or at the same time. Thus, the first conductive element 12 may be electrically connected to the first electrode (e.g., the negative electrode 101) of the first solar cell 10 and the first electrode (e.g., the P electrode 111) of the first protection element 11 through the first upper conductive circuit 13 directly, and may be not electrically connected to the second electrode (e.g., the positive electrode 102) of the first solar cell 10 and the second electrode (e.g., the N electrode 112) of the first protection element 11 directly.

Then, a lower transparent protection portion 57 may be formed to cover the lower conductive structure 64 and the second surface 554 (e.g., the bottom surface) of the main protection portion 55, so as to form the solar cell module 5 shown in FIG. 1.

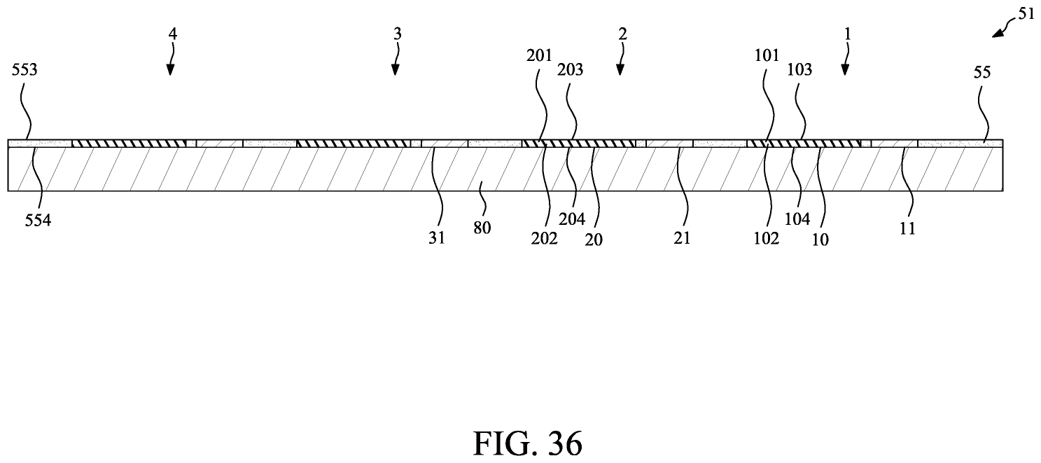

FIG. 36 through FIG. 38 illustrate an example of a method for manufacturing a solar cell module according to some embodiments of the present disclosure. In some embodiments, the method is for manufacturing a solar cell module such as the solar cell module 5c shown in FIG. 14 and FIG. 15. The initial several stages of the method corresponding to FIG. 36 through FIG. 38 are similar to the stages illustrated in FIG. 20 through FIG. 21, except that the conductive elements 62, 12, 22, 32, 42 in a metal block structure may be omitted in the method corresponding to FIG. 36 through FIG. 38.

Referring to FIG. 36, a main protection portion 55 may be formed to encapsulate the solar cells 60 (e.g., the first solar cell 10 and the second solar cell 20) and the protection elements 61 (e.g., the first protection element 11 and the second protection element 21). The main protection portion 55 may be the same as the main protection portion 55 of FIG. 14.

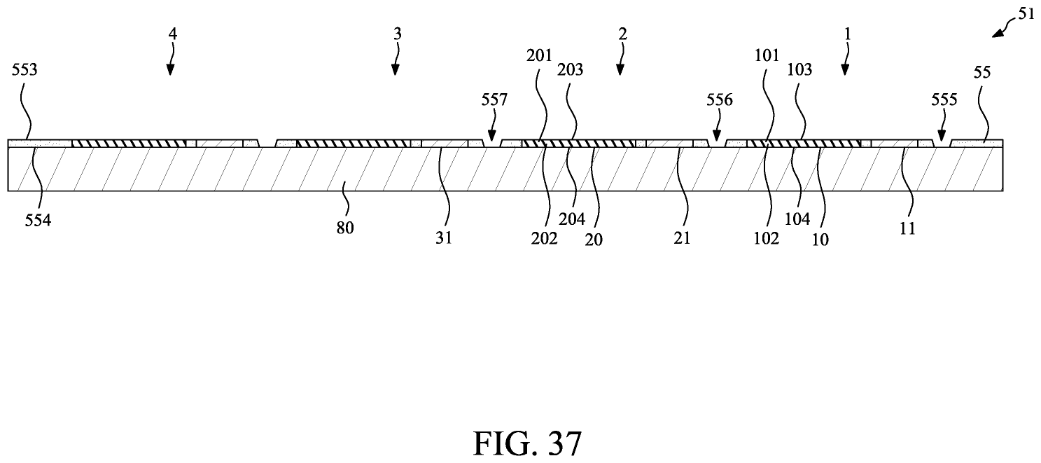

Referring to FIG. 37, a plurality of through holes may be formed to extend through the main protection portion 55 and expose the carrier 80. The through holes are disposed adjacent to the protection elements. For example, the through holes may include a first through hole 555, a second through hole 556 and a third through hole 557. The first through hole 555 is disposed adjacent to the first protection element 11. The second through hole 556 is disposed adjacent to the second protection element 21, and is disposed between the second protection element 21 and the first solar cell 10. The third through hole 557 is disposed adjacent to the third protection element 31, and is disposed between the third protection element 31 and the second solar cell 20.

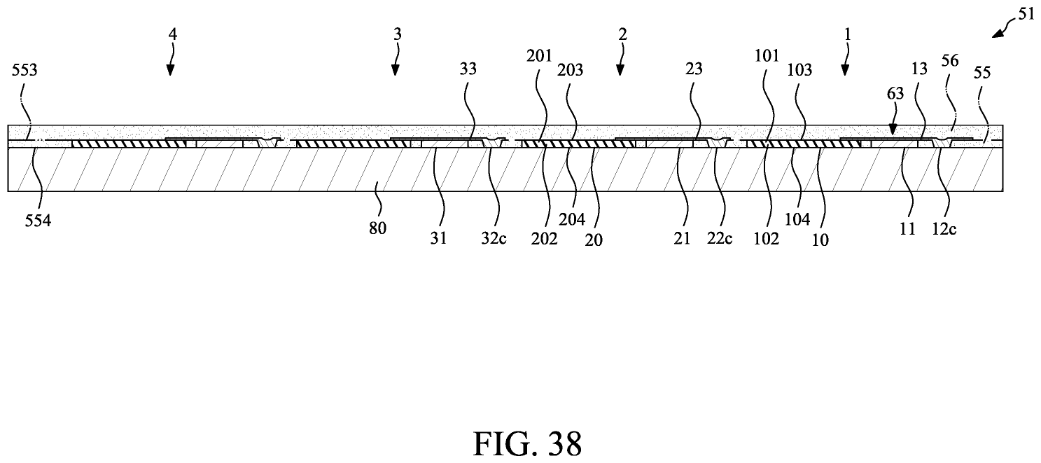

Referring to FIG. 38, an upper conductive structure 63 may be formed on the first surface 553 of the main protection portion 55. A plurality of conductive elements (e.g., interconnection vias) may be formed in the through holes. For example, the upper conductive structure 63 may include a first upper conductive circuit 13, a second upper conductive circuit 23 and a third upper conductive circuit 33. The conductive elements may include a first conductive element 12c, a second conductive element 22c and a third conductive element 32c. The first conductive element 12c may be a first interconnection via, and may be disposed in the first through hole 555 of the main protection portion 55. The first upper conductive circuit 13 and the first conductive element 12c (e.g., the first interconnection via) may be formed concurrently and integrally. The second conductive element 22c may be a second interconnection via, and may be disposed in the second through hole 556 of the main protection portion 55. The second upper conductive circuit 23 and the second conductive element 22c (e.g., the second interconnection via) may be formed concurrently and integrally. The third conductive element 32c may be a third interconnection via, and may be disposed in the third through hole 557 of the main protection portion 55. The third upper conductive circuit 33 and the third conductive element 32c (e.g., the third interconnection via) may be formed concurrently and integrally.

The following stages of the method corresponding to FIG. 36 through FIG. 38 are the same as, or at least similar to, the stages illustrated in FIG. 31 to FIG. 35 so as to obtain the solar cell module 5c shown in FIG. 14 and FIG. 15.

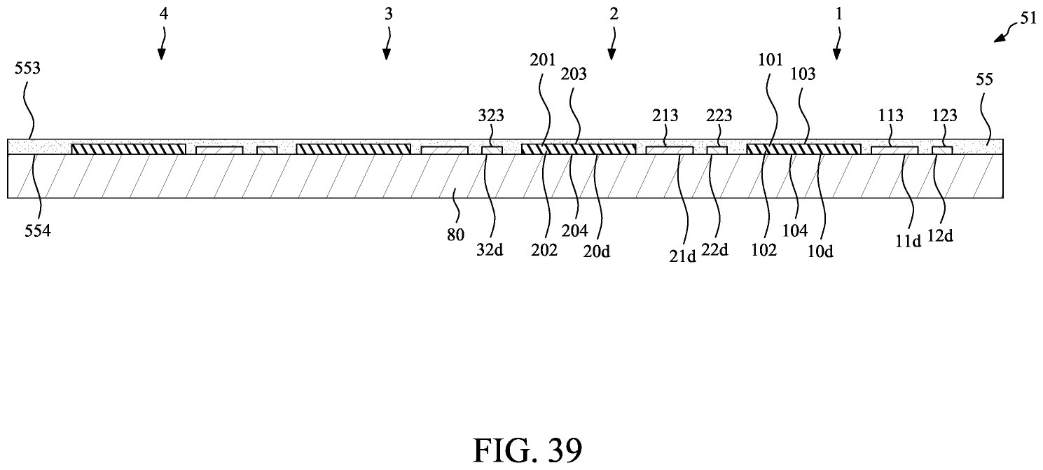

FIG. 39 through FIG. 44 illustrate an example of a method for manufacturing a solar cell module according to some embodiments of the present disclosure. In some embodiments, the method is for manufacturing a solar cell module such as the solar cell module 5d shown in FIG. 16 and FIG. 17. The initial several stages of the method corresponding to FIG. 39 through FIG. 44 are similar to the stages illustrated in FIG. 20 through FIG. 21, except that the thickness of the solar cell (e.g., the first solar cell 10d and the second solar cell 20d), the thickness of the protection element (e.g., the first protection element 11d and the second protection element 21d) and the thickness of the conductive element (e.g., the first conductive element 12d, the second conductive element 22d and the third conductive element 32d) may be less than the thickness of the main protection portion 55. In addition, the thickness of the solar cell (e.g., the first solar cell 10d and the second solar cell 20d), the thickness of the protection element (e.g., the first protection element 11d and the second protection element 21d) and the thickness of the conductive element (e.g., the first conductive element 12d, the second conductive element 22d and the third conductive element 32d) may be different from each other.

Referring to FIG. 39, a main protection portion 55 may be formed to cover the solar cell 60 (e.g., the first solar cell 10d and the second solar cell 20d), the protection element 61 (e.g., the first protection element 11d and the second protection element 21d) and the conductive element 62 (e.g., the first conductive element 12d, the second conductive element 22d and the third conductive element 32d). The main protection portion 55 may be the same as the main protection portion 55 of FIG. 16.

As shown in FIG. 39, the main protection portion 55 may cover the first surface of the solar cell (e.g., the first surface 103 (top surface) of the first solar cell 10d and the first surface 203 (top surface) of the second solar cell 20d), the first surface of the protection element (e.g., the first surface 113 (top surface) of the first protection element 11d and the first surface 213 (top surface) of the second protection element 21d) and the first surface of the conductive element (e.g., the first surface 123 (top surface) of the first conductive element 12d, the first surface 223 (top surface) of the second conductive element 22d and the first surface 323 (top surface) of the third conductive element 32d).

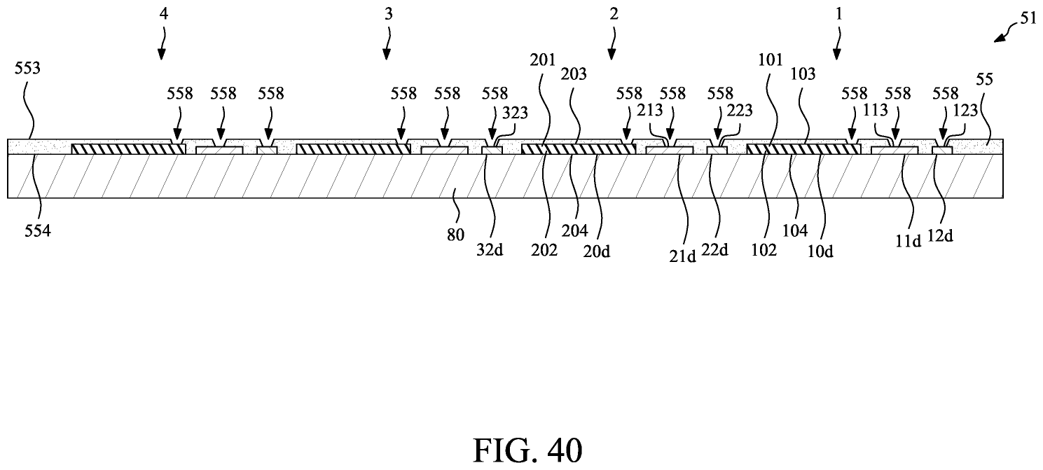

Referring to FIG. 40, a plurality of openings 558 may be formed to extend through a plurality of portions of the main protection portion 55 that are disposed on the solar cells 10d, 20d, the protection elements 11d, 21d and the conductive element 12d, 22d, 32d, so as to expose the solar cells 10d, 20d, the protection elements 11d, 21d and the conductive element 12d, 22d, 32d.

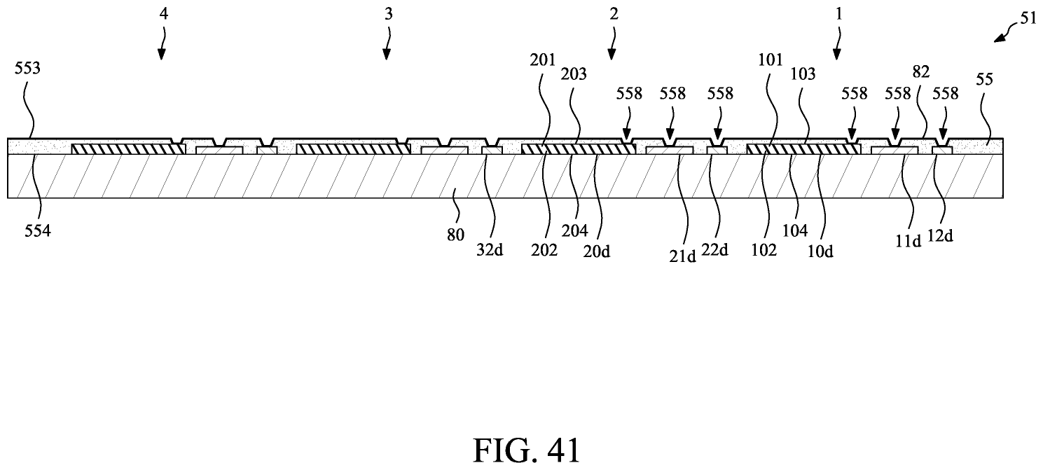

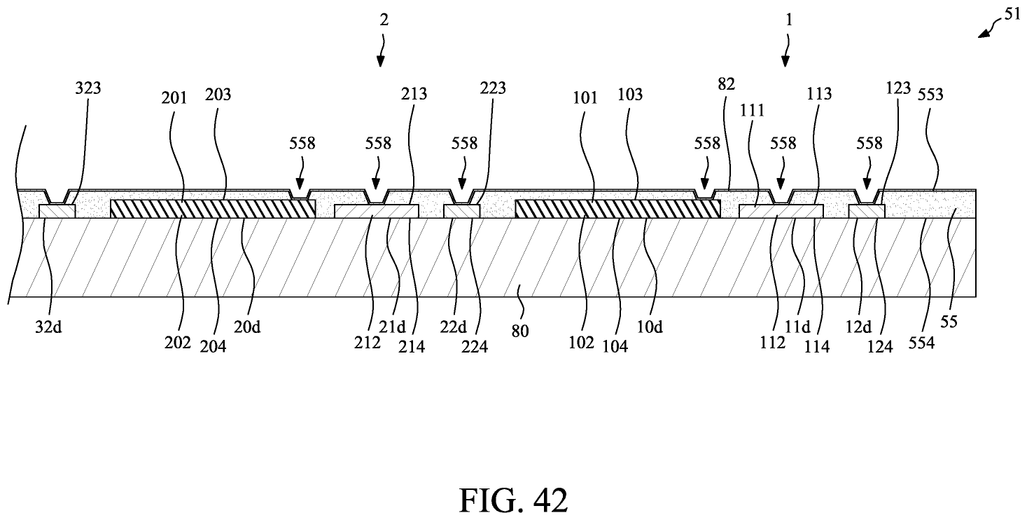

Referring to FIG. 41 and FIG. 42, wherein FIG. 42 is a partially enlarged view of FIG. 41, a seed layer 82 may be formed on the first surface 553 of the main protection portion 55 and in the openings 558 by, for example, electroplating, so as to contact the solar cells 10d, 20d, the protection elements 11d, 21d and the conductive element 12d, 22d, 32d.

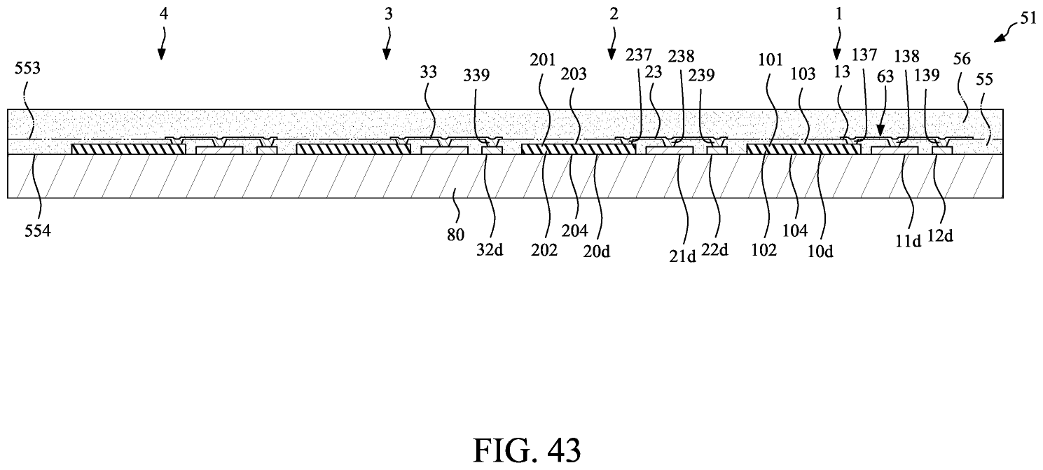

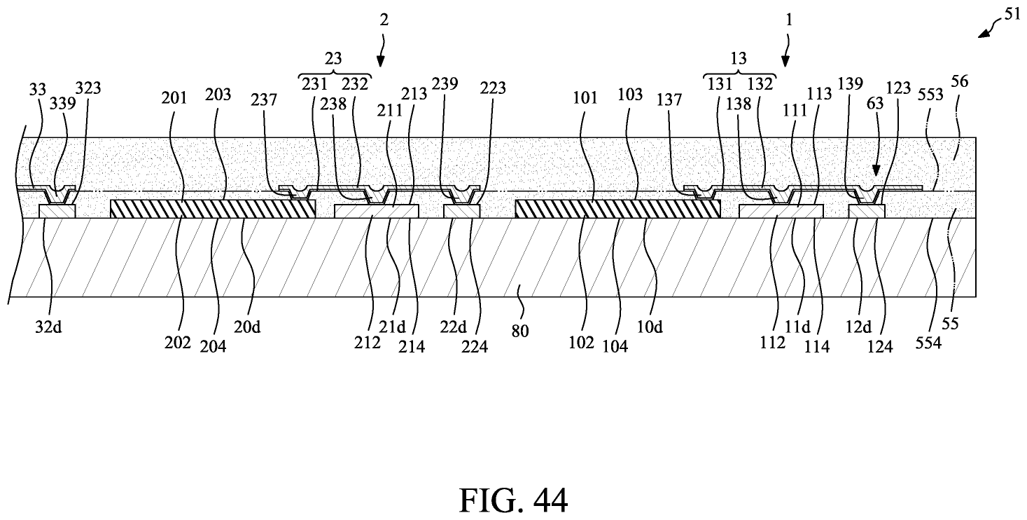

Referring to FIG. 43 and FIG. 44, wherein FIG. 44 is a partially enlarged view of FIG. 43, a conductive material 132, 232 may be formed on the seed layer 82 by, for example, electroplating. Then, the seed layer 82 may be patterned so as to form the upper conductive structure 63 on the first surface 553 of the main protection portion 55, and form a plurality of upper conductive vias 137, 138, 139, 237, 238, 239, 339 in the openings 558. The patterned seed layer 82 may include, for example, the seed layers 131, 231. For example, the upper conductive structure 63 may include a first upper conductive circuit 13, a second upper conductive circuit 23 and a third upper conductive circuit 33. The upper conductive vias 137, 138, 139, 237, 238, 239, 339 may extend through a plurality of portions of the main protection portion 55 that are disposed on the solar cells 10d, 20d, the protection elements 11d, 21d and the conductive element 12d, 22d, 32d, and may electrically connect the upper conductive circuits 13, 23, the first surfaces 103, 203 (top surfaces) of the solar cells 10d, 20d, the first surfaces 113, 213 (top surface) of the protection elements 11d, 21d and the first surfaces 123, 223, 323 (top surfaces) of the conductive elements 12d, 22d, 32d.

In one embodiment, the first upper conductive circuit 13 and the upper conductive vias 137, 138, 139 may be formed concurrently and integrally. The second upper conductive circuit 23 and the upper conductive vias 237, 238, 239 may be formed concurrently and integrally. The third upper conductive circuit 33 and the upper conductive via 339 may be formed concurrently and integrally. The upper conductive vias 137, 138, 139 may include a seed layer 131 and a conductive material 132 disposed on the seed layer 131. The upper conductive vias 237, 238, 239 may include a seed layer 231 and a conductive material 232 disposed on the seed layer 231.

The following stages of the method corresponding to FIG. 39 through FIG. 44 are the same as, or at least similar to, the stages illustrated in FIG. 31 to FIG. 35 so as to obtain the solar cell module 5d shown in FIG. 16 and FIG. 17.

The foregoing embodiments are merely illustrative of the principles and effects of the disclosure, and are not to be construed as limiting the disclosure. Thus, those skilled in the art will appreciate that various modifications and changes can be made to the above embodiments without departing from the spirit of the disclosure. The scope of the disclosure is to be determined by the following claims. Moreover, the scope of the application is not intended to be limited to the particular embodiments described in the specification. A person of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the disclosure.

What is claimed is:

1. A solar cell module, comprising:
a first unit including a first solar cell and a first protection element, wherein the first solar cell and the first protection element are electrically coupled in parallel; and
a second unit including a second solar cell and a second protection element, wherein the second solar cell and the second protection element are electrically coupled in parallel, and the first unit is electrically connected to the second unit.

2. The solar cell module according to claim 1, wherein the first unit and the second unit are electrically coupled in series.

3. The solar cell module according to claim 1, wherein the first protection element is a first diode element, and the second protection element is a second diode element.

4. The solar cell module according to claim 1, wherein a first electrical path is formed between the first solar cell and the first protection element, a second electrical path is formed between the second solar cell and the second protection element, and a length of the first electrical path is substantially equal to a length of the second electrical path.

5. The solar cell module according to claim 1, wherein the first unit further includes a first conductive element electrically connecting a first electrode of the first solar cell and a first electrode of the first protection element, wherein the first conductive element does not electrically connect a second electrode of the first solar cell and a second electrode of the first protection element.

6. The solar cell module according to claim 5, wherein the first protection element is disposed between the first solar cell and the first conductive element.

7. The solar cell module according to claim 5, wherein the first conductive element is a metal block structure.

8. The solar cell module according to claim 5, wherein the second unit further includes a second conductive element electrically connecting a first electrode of the second solar cell and a first electrode of the second protection element, wherein the second conductive element does not electrically connect a second electrode of the second solar cell and a second electrode of the second protection element, wherein the second conductive element electrically connects the second electrode of the first solar cell and the second electrode of the first protection element.

9. The solar cell module according to claim 8, wherein the second protection element is disposed between the second solar cell and the second conductive element.

10. The solar cell module according to claim 8, wherein the second conductive element is a metal block structure.

11. A solar cell module, comprising:
a plurality of solar cells; and
a plurality of protection elements, disposed adjacent to the plurality of solar cells, wherein at least one of the plurality of protection elements and at least one of the plurality of solar cells are electrically coupled in parallel.

12. The solar cell module according to claim 11, wherein one of the plurality of protection elements is disposed between adjacent two of the plurality of solar cells.

13. The solar cell module according to claim 11, wherein the plurality of solar cells are electrically coupled in series.

14. The solar cell module according to claim 11, further comprising a plurality of conductive elements, wherein one of the plurality of conductive elements electrically connects different electrodes of adjacent two of the plurality of solar cells.

15. The solar cell module according to claim 11, further comprising a plurality of conductive circuits formed by a plating process.

16. The solar cell module according to claim 15, wherein each of the plurality of conductive circuits includes a seed layer and a conductive material disposed on the seed layer.

17. The solar cell module according to claim 11, further comprising:
a main protection portion, encapsulating the plurality of solar cells and the plurality of protection elements;
an upper transparent protection portion, covering an upper portion of the main protection portion, a plurality of upper portions of the plurality of solar cells and a plurality of upper portions of the plurality of protection elements; and
a lower transparent protection portion, covering a lower portion of the main protection portion, a plurality of lower portions of the plurality of solar cells and a plurality of lower portions of the plurality of protection elements.

18. The solar cell module according to claim 17, wherein an upper visible interface is formed between the upper transparent protection portion and the main protection portion, and a lower visible interface is formed between the lower transparent protection portion and the main protection portion.

19. The solar cell module according to claim 17, wherein there is no obvious interface between the upper transparent protection portion and the main protection portion, and there is no obvious interface between the lower transparent protection portion and the main protection portion.

20. The solar cell module according to claim 17, wherein the main protection portion covers and protects a plurality of top surfaces of the plurality of solar cells and a plurality of top surfaces of the plurality of protection elements, the solar cell module further comprises an upper conductive structure disposed on the main protection portion, the upper conductive structure includes a plurality of upper conductive circuits and a plurality of conductive vias, the plurality of conductive vias extend through a plurality of portions of the main protection portion on the plurality of solar cells and the plurality of protection elements, and electrically connect the plurality of upper conductive circuits to the plurality of top surfaces of the plurality of solar cells and the plurality of top surfaces of the plurality of protection elements.

21. The solar cell module according to claim 20, wherein the plurality of upper conductive circuits and the plurality of conductive vias are formed integrally.

22. The solar cell module according to claim 20, wherein the upper conductive structure further includes a plurality of upper interconnection vias adjacent to the plurality of protection elements, and extending through the main protection portion.

23. The solar cell module according to claim 17, wherein the main protection portion exposes a plurality of bottom surfaces of the plurality of solar cells and a plurality of bottom surfaces of the plurality of protection elements, the solar cell module further comprises a lower conductive structure disposed on a bottom surface of the main protection portion, the plurality of bottom surfaces of the plurality of solar cells and the plurality of bottom surfaces of the plurality of protection elements, wherein the lower conductive structure includes a plurality of lower conductive circuits electrically connecting to the plurality of bottom surfaces of the plurality of solar cells and the plurality of bottom surfaces of the plurality of protection elements.

24. The solar cell module according to claim 23, wherein the bottom surface of the main protection portion is substantially coplanar with the plurality of bottom surfaces of the plurality of solar cells and the plurality of bottom surfaces of the plurality of protection elements.

25. A method for manufacturing a solar cell module, comprising:
(a) disposing a plurality of solar cells and a plurality of protection elements on a carrier; and
(b) electrically coupling the plurality of protection elements and the plurality of solar cells in parallel and in one-to-one relationships, and electrically connecting the plurality of solar cells with one another.

26. The method according to claim 25, wherein the step (a) further includes: disposing a plurality of conductive elements on the carrier, and wherein the step (b) further includes: electrically connecting the plurality of conductive elements to different electrodes of adjacent two of the plurality of solar cells.

27. The method according to claim 25, wherein after the step (a), the method further includes:
(a1) forming a main protection portion to encapsulate the plurality of solar cells and the plurality of protection elements;
wherein the step (b) includes:
(b1) forming an upper conductive structure and a lower conductive structure on a top surface and a bottom surface of the main protection portion, respectively, so as to electrically couple the plurality of protection elements and the plurality of solar cells in parallel.

28. The method according to claim 27, further comprising:
(c) forming an upper transparent protection portion to cover the upper conductive structure and the top surface of the main protection portion; and
(d) forming a lower transparent protection portion to cover the lower conductive structure and the bottom surface of the main protection portion.
